(19) United States
(12) Patent Application Publication
(10) Pub. No.: US 2025/0151535 A1
(43) Pub. Date: May 8, 2025

(54) DISPLAY DEVICE AND METHOD FOR MANUFACTURING THE SAME

(71) Applicant: Samsung Display Co., LTD., Yongin-si (KR)

(72) Inventor: Jong Hyun CHOI, Yongin-si (KR)

(73) Assignee: Samsung Display Co., LTD., Yongin-si (KR)

(21) Appl. No.: 18/775,508

(22) Filed: Jul. 17, 2024

(30) Foreign Application Priority Data
Nov. 6, 2023 (KR) 10-2023-0151778

(51) Int. Cl. H10K 59/124; H10K 59/12; H10K 59/126

(52) U.S. Cl. CPC H10K 59/124; H10K 59/1201; H10K 59/126

(57) ABSTRACT

A display device includes a first transistor including a first active layer disposed in a first semiconductor layer on a substrate, and a first gate electrode overlapping the first active layer, a second transistor including a second active layer disposed in a second semiconductor layer on the substrate, and a second gate electrode overlapping the second active layer, a dummy pattern disposed in the first semiconductor layer and spaced apart from the first active layer, inorganic insulating layers disposed on the substrate, and covering the first active layer, the dummy pattern, the first gate electrode, the second active layer, and the second gate electrode, a dummy hole disposed on the dummy pattern and penetrating the inorganic insulating layers, and a shielding layer disposed at least inside the dummy hole, and covering side surfaces of the inorganic insulating layers exposed by the dummy hole.

### CROSS-REFERENCE TO RELATED APPLICATION(S)

This application claims priority to and benefits of Korean Patent Application No. 10-2023-0151778 under 35 U.S.C. 119, filed on Nov. 6, 2023, in the Korean Intellectual Property Office (KIPO), the entire contents of which are incorporated herein by reference.

### BACKGROUND

### 1. Technical Field

The disclosure relates to a display device and a method for manufacturing the same.

### 2. Description of the Related Art

The importance of display devices has steadily increased with the development of multimedia technology. Along with this trend, various display devices including a light emitting display device are being developed.

### SUMMARY

Aspects of the disclosure provide a display device capable of reducing deterioration of a transistor and a method for manufacturing the same.

However, aspects of the disclosure are not restricted to the one set forth herein. The above and other aspects of the disclosure will become more apparent to one of ordinary skill in the art to which the disclosure pertains by referencing the detailed description of the present disclosure given below.

According to an embodiment of the disclosure, a display device may include a first transistor including a first active layer disposed in a first semiconductor layer on a substrate, and a first gate electrode overlapping the first active layer in a plan view, a second transistor including a second active layer disposed in a second semiconductor layer on the substrate, and a second gate electrode overlapping the second active layer in a plan view, a dummy pattern disposed in the first semiconductor layer and spaced apart from the first active layer, inorganic insulating layers disposed on the substrate, and covering the first active layer, the dummy pattern, the first gate electrode, the second active layer, and the second gate electrode, a dummy hole disposed on the dummy pattern and penetrating the inorganic insulating layers, and a shielding layer disposed at least inside the dummy hole, and covering side surfaces of the inorganic insulating layers exposed by the dummy hole.

In an embodiment, the display device may further include an organic insulating layer disposed on the inorganic insulating layers, and covering the first transistor, the second transistor, and the shielding layer.

In an embodiment, the shielding layer may be a conductive pattern including a metal.

In an embodiment, the second transistor may further include a first electrode disposed on the inorganic insulating layers and connected to a source region or a drain region of the first active layer, and the first electrode and the shielding layer may be disposed in a same layer on the substrate and may include a same conductive material.

In an embodiment, the display device may further include a power line adjacent to the dummy pattern. The shielding layer may be connected to the power line.

In an embodiment, the power line may be disposed on the inorganic insulating layers, and the display device may further include a connection pattern disposed between the first semiconductor layer and a conductive layer in which the shielding layer is disposed and connecting the shielding layer to the power line.

In an embodiment, the connection pattern and the first gate electrode or the second gate electrode may be disposed in a same layer.

In an embodiment, the display device may further include a capacitor electrode disposed between a conductive layer in which the first gate electrode is disposed and a conductive layer in which the second gate electrode is disposed on the substrate. The connection pattern and the capacitor electrode may be disposed in a same layer.

In an embodiment, the shielding layer may be an inorganic insulating layer including nitrogen.

In an embodiment, the shielding layer may be a single-layer inorganic insulating layer including a silicon nitride layer or a silicon oxynitride layer.

In an embodiment, the shielding layer may be a multi-layer inorganic insulating layer including a silicon nitride layer or a silicon oxynitride layer and a silicon oxide layer.

In an embodiment, the shielding layer may have a refractive index of greater than or equal to about 1.6.

In an embodiment, the display device may further include pixels disposed in a display area on the substrate, and a driving circuit disposed in a non-display area on the substrate and connected to the pixels. The first transistor and the second transistor may be provided in the driving circuit.

In an embodiment, the dummy pattern, the dummy hole, and the shielding layer may be disposed adjacent to the driving circuit.

In an embodiment, the dummy pattern, the dummy hole, and the shielding layer may be disposed between stage circuits provided in the driving circuit.

According to an embodiment of the disclosure, a method for manufacturing a display device may include sequentially forming, on a substrate, a first active layer and a dummy pattern, a first inorganic insulating layer covering the first active layer and the dummy pattern, a first gate electrode, a second inorganic insulating layer covering the first gate electrode, a second active layer, a third inorganic insulating layer covering the second active layer, a second gate electrode, and a fourth inorganic insulating layer covering the second gate electrode, forming a contact hole penetrating the first to fourth inorganic insulating layers to expose a part of the first active layer and a dummy hole penetrating the first to fourth inorganic insulating layers to expose a part of the dummy pattern, and forming a first electrode connected to the first active layer through the contact hole penetrating the first to fourth inorganic insulating layers, and a shielding layer at least inside the dummy hole to cover side surfaces of the first to fourth inorganic insulating layers exposed by the dummy hole.

In an embodiment, the method may further include forming an organic insulating layer covering the first electrode and the shielding layer, on the first to fourth inorganic insulating layers.

In an embodiment, in the forming of the first electrode and the shielding layer, the first electrode and the shielding layer may be formed simultaneously using a conductive material including a metal.

In an embodiment, the method may further include forming a power line connected to the shielding layer, on the first to fourth inorganic insulating layers.

In an embodiment, the forming of the first electrode and the shielding layer may include forming the first electrode using a conductive material, and forming the shielding layer using an inorganic insulating material including nitrogen.

In accordance with the display device and the method for manufacturing the same according to embodiments, a dummy pattern and a dummy hole may be formed adjacent to circuit elements including a transistor. Accordingly, patterns of a display panel may be formed more uniformly, and the characteristics of circuit elements may be controlled uniformly.

Further, in accordance with the display device and the method for manufacturing the same according to embodiments, a shielding layer that covers the side surfaces of inorganic insulating layers exposed by the dummy hole may be formed in the dummy hole. Accordingly, deterioration of circuit elements located adjacent to the dummy hole may be reduced. Further, the distance between a transistor and a dummy hole may be appropriately shortened, and a non-display area may be reduced.

In some embodiments, the shielding layer may be a conductive pattern including or containing a metal, and may be connected to a power line. Accordingly, the operating characteristics of a display device may be stabilized.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to one embodiment;

FIG. 2 is a plan view illustrating the display device of FIG. 1;

FIG. 3 is a plan view illustrating the display panel according to one embodiment;

FIG. 4 is a schematic diagram of an equivalent circuit of the pixel according to one embodiment;

FIG. 5 is a schematic cross-sectional view illustrating the display panel according to one embodiment;

FIG. 6 is a plan view showing a part of the display panel according to one embodiment;

FIG. 7 is a plan view schematically showing a driver transistor and a dummy pattern according to one embodiment;

FIG. 8 is a schematic cross-sectional view illustrating the display panel according to one embodiment;

FIG. 9 is a schematic cross-sectional view illustrating the display panel according to one embodiment;

FIG. 10 is a schematic cross-sectional view illustrating the display panel according to one embodiment;

FIG. 11 is a schematic cross-sectional view illustrating the display panel according to one embodiment;

FIG. 12 is a schematic cross-sectional view illustrating the display panel according to one embodiment;

FIG. 13 is a schematic cross-sectional view illustrating the display panel according to one embodiment;

FIGS. 14 to 18 are schematic cross-sectional views illustrating a manufacturing method of the display device according to one embodiment; and

FIGS. 19 and 20 are schematic cross-sectional views illustrating a method for manufacturing the display device according to one embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

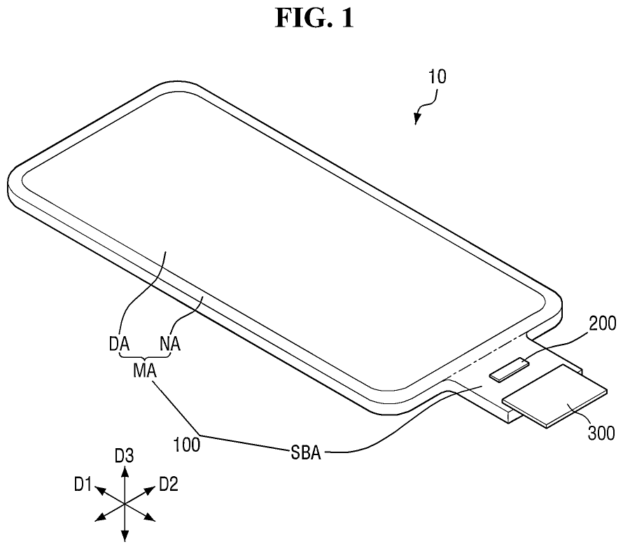

FIG. 1 is a perspective view illustrating a display device 10 according to one embodiment.

Referring to FIG. 1, the display device 10 may be a device for displaying an image. The display device 10 may be used as a display screen of various products such as televisions, laptop computers, monitors, billboards and the Internet of Things (IoT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs).

In one embodiment, the display device 10 may be a light emitting display device including a light emitting element. The display device 10 may be another type of display device other than a light emitting display device. In the following, embodiments in which the display device 10 is an organic light emitting display device are described, but the type of display device 10 according to the embodiments is not limited thereto.

In FIG. 1, a first direction D1, a second direction D2, and a third direction D3 are indicated. With respect to the image display surface of the display device 10, the first direction D1 may be a lengthwise direction, a column direction, or a vertical direction of the display device 10, and the second direction D2 may be a direction intersecting the first direction D1, for example, a widthwise direction, a row direction, or a horizontal direction of the display device 10. The third direction D3 may be a direction intersecting the first direction D1 and the second direction D2 and may be, for example, a thickness direction or a height direction of the display device 10.

The display device 10 may include a display panel 100 including pixels and a first driving circuit (e.g., a panel-embedded gate driving circuit). The display device 10 may further include a second driving circuit 200 and a circuit board 300 connected to the pixels and/or the first driving circuit.

The display panel 100 may include a main region MA including a display area DA in which an image is displayed, and a sub-region SBA located on a side of the main region MA. The display panel 100 may be formed to be rigid to maintain an overall flat shape, or may be formed to be flexible that can be curved, warped, bent, folded, or rolled in at least one part.

The main region MA may include the display area DA and a non-display area NA adjacent to the display area DA. The non-display area NA may be positioned at an edge of the main region MA and may be in contact with the sub-region SBA.

In one embodiment, the main region MA may have a substantially rectangular shape in a plan view including long sides in the first direction D1 and short sides in the second direction D2. A corner portion at which the long side and the short side of the main region MA meet may be rounded or right-angled. The shape of the main region MA may be variously changed according to embodiments.

The display area DA may be an area in which pixels are arranged, and may be an area in which an image is displayed by pixels. The display area DA may be positioned in the center of the main region MA and occupy most of the area in the main region MA.

In one embodiment, the display area DA may have a shape corresponding to the shape of the main region MA. For example, the display area DA may include a long side in the first direction D1 and a short side in the second direction D2 and may have an approximately rectangular shape in a plan view. A corner portion at which the long side and the short side of the display area DA meet may be rounded or right-angled. The shape of the display area DA may be variously changed according to embodiments.

The non-display area NA may be located immediately adjacent to the display area DA. For example, the non-display area NA may be located at the edge of the main region MA, and may surround the display area DA in a plan view. The non-display area NA may be in contact with the sub-region SBA.

Wires (or parts of wires) connected to pixels may be disposed in the non-display area NA. In one embodiment, the first driving circuit for supplying first driving signals to pixels PX may be further disposed in the non-display area NA.

In one embodiment, the first driving circuit may be a gate driving circuit for supplying respective gate signals (e.g., scan signals and/or emission control signals) to the pixels PX. For example, the first driving circuit may include stage circuits for generating scan signals, and/or stage circuits for generating emission control signals of the pixels PX.

The sub-region SBA may be located on a side of the main region MA. For example, the sub-region SBA may protrude in the first direction D1 from a side of the main region MA. For example, the sub-region SBA may protrude in the first direction D1 from the lower end of the main region MA.

In one embodiment, the sub-region SBA may have a narrower width than the main region MA. For example, with respect to the second direction D2, the sub-region SBA may have a narrower width than the main region MA.

Wires (or parts of wires) and pads may be provided in the sub-region SBA. For example, in the sub-region SBA, wires and pads connected to the pixels and/or the first driving circuit positioned in the main region MA and to the second driving circuit 200 and/or the circuit board 300 positioned in the sub-region SBA may be disposed. In describing embodiments, the term “connect” may include electrical connection and/or physical connection.

In one embodiment, the second driving circuit 200 may be mounted in the sub-region SBA. The circuit board 300 may be disposed on a portion of the sub-region SBA.

The second driving circuit 200 may be connected to the pixels PX of the display area DA. The second driving circuit 200 may include a data driving circuit to drive pixels. The second driving circuit 200 may supply respective data signals to the pixels PX.

In one embodiment, the second driving circuit 200 may be implemented as an integrated circuit chip (IC) and mounted in the sub-region SBA. In another embodiment, the second driving circuit 200 may be provided or mounted on the circuit board 300 on the sub-region SBA or may be provided or mounted on another circuit board connected to the display panel 100 through the circuit board 300.

The circuit board 300 may be disposed on a part of the sub-region SBA. For example, the circuit board 300 may be bonded on the pads positioned on a portion (e.g., a lower edge) of the sub-region SBA, and may supply or transmit power voltages and driving signals for driving the display panel 100 and/or the second driving circuit 200 to the display panel 100. For example, the circuit board 300 may supply input image data (e.g., digital image data), driving signals (e.g., timing signals) for driving the first driving circuit and/or the second driving circuit 200, and power voltages for driving the pixels, the first driving circuit, and/or the second driving circuit 200 to the display panel 100. The circuit board 300 may be a flexible film such as a flexible printed circuit board (FPCB), a printed circuit board (PCB), or a chip on film (COF), but the disclosure is not limited thereto.

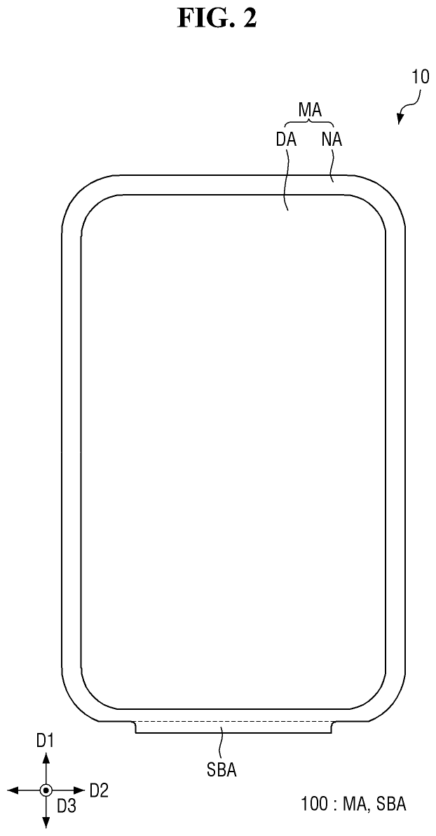

FIG. 2 is a plan view illustrating the display device 10 of FIG. 1. FIG. 1 schematically shows the display device 10 unfolded without bending, and FIG. 2 schematically shows the display device 10 bent in the sub-region SBA. For example, FIG. 1 schematically illustrates a state in which the sub-region SBA is spread out parallel to the main region MA, and FIG. 2 schematically illustrates a state in which the sub-region SBA is bent such that a part of the sub-region SBA is positioned below the main region MA.

Referring to FIG. 2 in addition to FIG. 1, the sub-region SBA of the display panel 100 may be formed flexible so that at least a part of the sub-region SBA can be curved, bent, folded, or rolled. In one embodiment, the sub-region SBA may be bent at a portion adjacent to the main region MA. Accordingly, a portion of the sub-region SBA in which the second driving circuit 200 is mounted may be positioned below the main region MA.

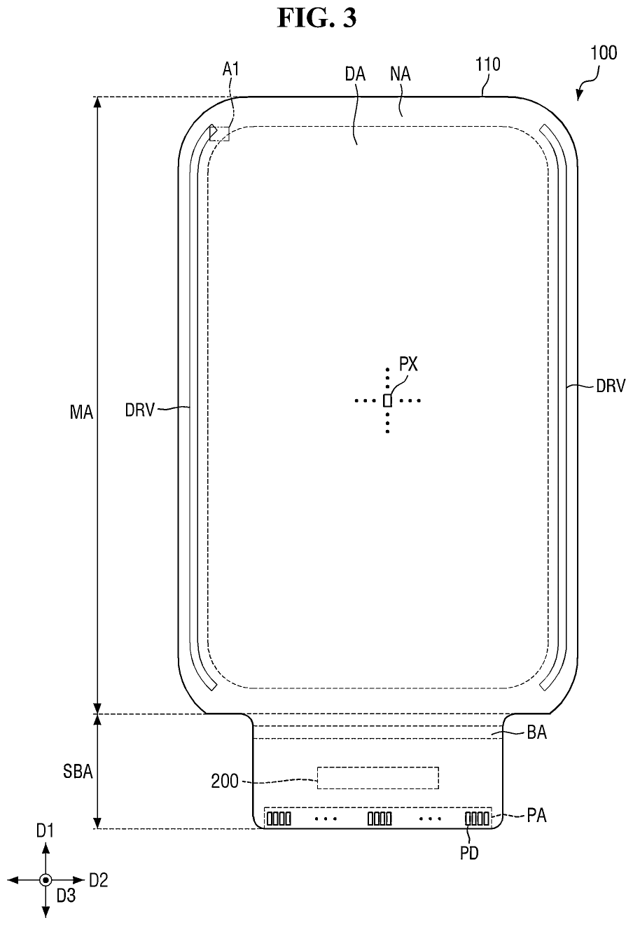

FIG. 3 is a plan view illustrating the display panel 100 according to one embodiment. FIG. 3 schematically shows the display panel 100 in an unbent and unfolded state.

Referring to FIG. 3 in addition to FIGS. 1 and 2, the display panel 100 may include the main region MA including the display area DA and the non-display area NA, and the sub-region SBA including a pad area PA. In one embodiment, the sub-region SBA may further include a driving circuit mounting area where the second driving circuit 200 is mounted.

In one embodiment, the sub-region SBA may further include a bending area BA. In one embodiment, the bending area BA may be adjacent to the main region MA. The display panel 100 may be bendable in the sub-region SBA, so that a part of the sub-region SBA may be positioned below the main region MA.

The display panel 100 may include a substrate 110 (or base layer) forming a base surface. The substrate 110 may include the main region MA including the display area DA and the non-display area NA. In one embodiment, the substrate 110 may further include the sub-region SBA protruding from the main region MA.

The display panel 100 may include the pixels PX, and the pads PD disposed and/or formed on the substrate 110. In one embodiment, the display panel 100 may further include a first driving circuit DRV and wires disposed and/or formed on the substrate 110. The wires may be connected to the pixels PX, the first driving circuit DRV, the second driving circuit 200, and/or the pads PD.

The pixels PX may be disposed in the display area DA. Wires (or parts of wires) connected to the pixels PX may be further disposed in the display area DA. For example, scan lines, data lines, and pixel power lines connected to the pixels PX may be further disposed in the display area DA. In the display device 10 in which the emission timing of the pixels PX is controlled by the emission control signal, emission control lines for transmitting the emission control signals to the pixels PX may be further disposed in the display area DA.

The first driving circuit DRV may be disposed in the non-display area NA. The first driving circuit DRV may be connected to the pads PD provided in the pad area PA. The first driving circuit DRV may receive gate control signals (e.g., gate start pulse and gate clock signals) and gate power voltages (e.g., gate high voltage and gate low voltage) required for generating gate signals from the pads PD. The first driving circuit DRV may be connected to the pixels PX through gate lines (for example, the scan lines and/or the emission control lines), and may supply gate signals (for example, the scan signals and/or the emission control signals) to the pixels PX.

The first driving circuit DRV may be located on at least one side of the display area DA. For example, the first driving circuit DRV may be located only on one side (e.g., left side or right side) of the display area DA, or may be located on sides (e.g., left side and right side) of the display area DA. The position and/or number of the first driving circuit DRV may vary depending on embodiments.

In one embodiment, the first driving circuit DRV may be an embedded circuit provided and/or formed in the display panel 100 together with the pixels PX. For example, the first driving circuit DRV may be formed on the display panel 100 by a gate-in panel method.

The pads PD may be disposed in the pad area PA. The pads PD may connect the display panel 100 and/or the second driving circuit 200 to the circuit board 300 or the like. The pads PD may include power pads and signal pads for transmitting power voltages and driving signals required for driving the pixels PX, the first driving circuit DRV, and/or the second driving circuit 200 into the display panel 100. The circuit board 300 may be disposed or bonded on the pad area PA.

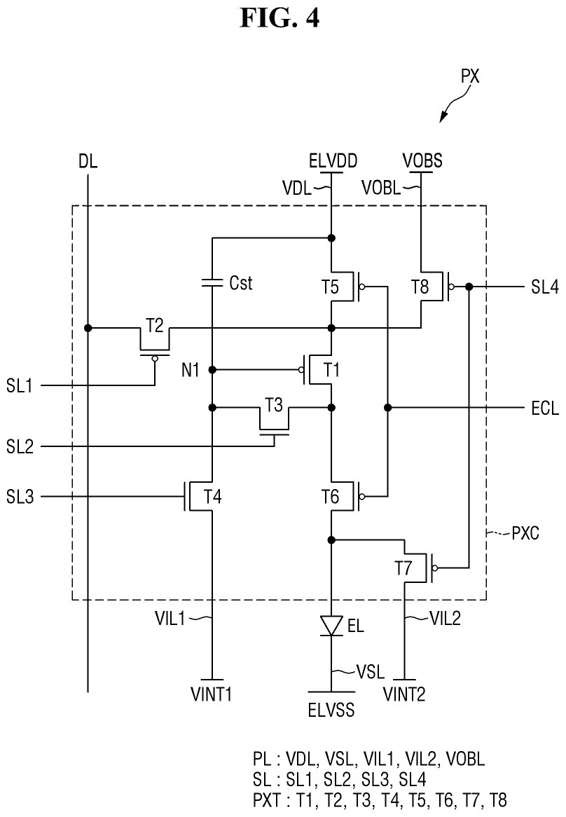

FIG. 4 is a schematic diagram of an equivalent circuit of the pixel PX according to one embodiment.

Referring to FIG. 4 in addition to FIGS. 1 to 3, each of the pixels PX may include a pixel circuit PXC and a light emitting element EL connected to the pixel circuit PXC. FIG. 4 schematically illustrates an embodiment in which the pixel circuit PXC provided in the pixel PX includes a driving transistor and multiple switching transistors. In one embodiment, scan lines SL connected to the pixel PX may include a first scan line SL1, a second scan line SL2, a third scan line SL3, and a fourth scan line SL4, and pixel power lines PL connected to the pixel PX may include a first pixel power line VDL, a second pixel power line VSL, a first initialization power line VIL1, a second initialization power line VIL2, and a bias power line VOBL. The pixel PX may be further connected to the data line DL and an emission control line ECL. The configuration of the pixel circuit PXC and the type of wires connected to the pixel circuit PXC may be variously changed according to embodiments.

The pixel circuit PXC may control the light emitting timing and luminance of the light emitting element EL by controlling the driving current supplied to the light emitting element EL. For example, the pixel circuit PXC may include pixel transistors PXT and a storage capacitor Cst that control the driving current in response to at least one scan signal and data signal supplied to the corresponding pixel PX. In one embodiment, the pixel transistors PXT may include a driving transistor T1 and first to seventh switching transistors T2 to T8.

The driving transistor T1 may include a gate electrode connected to a first node N1, a first electrode connected to the pixel power line VDL via the fourth switching transistor T5, and a second electrode connected to the light emitting element EL via the fifth switching transistor T6. One of the first electrode and the second electrode may be a source electrode and another one of the first electrode and the second electrode may be a drain electrode. The driving transistor T1 may control the driving current (e.g., the source-drain current of the driving transistor T1) flowing between the first electrode and the second electrode according to the voltage (e.g., the voltage of the first node N1 corresponding to the voltage of the data signal) applied to the gate electrode.

The first switching transistor T2 may include a gate electrode connected to the first scan line SL1, a first electrode connected to the data line DL, and a second electrode connected to the first electrode of the driving transistor T1. The first switching transistor T2 may be turned on by the first scan signal supplied to the first scan line SL1 to connect the first electrode of the driving transistor T1 to the data line DL. In case that the first switching transistor T2 is turned on, the voltage of the data signal supplied to the data line DL may be applied to the first electrode of the driving transistor T1.

The second switching transistor T3 may include a gate electrode connected to the second scan line SL2, a first electrode connected to the second electrode of the driving transistor T1, and a second electrode connected to a gate electrode (or the first node N1) of the driving transistor T1. The second switching transistor T3 may be turned on by the second scan signal supplied to the second scan line SL2 to connect the gate electrode of the driving transistor T1 to the second electrode. In case that the second switching transistor T3 is turned on, the driving transistor T1 may be driven as a diode.

The third switching transistor T4 may include a gate electrode connected to the third scan line SL3, a first electrode connected to the gate electrode of the driving transistor T1, and a second electrode connected to the first initialization power line VIL1. The third switching transistor T4 may be turned on by the third scan signal supplied to the third scan line SL3 to connect the gate electrode of the driving transistor T1 to the first initialization power line VIL1. In case that the third switching transistor T4 is turned on, a first initialization voltage VINT1 (e.g., the gate initialization voltage) of the first initialization power line VIL1 may be applied to the gate electrode of the driving transistor T1.

The fourth switching transistor T5 may include a gate electrode connected to the emission control line ECL, a first electrode connected to the first pixel power line VDL, and a second electrode connected to the first electrode of the driving transistor T1. The fourth switching transistor T5 may be turned on by the emission control signal supplied to the emission control line ECL, and thus may connect the first electrode of the driving transistor T1 to the first pixel power line VDL to which a first pixel power voltage ELVDD is applied. In case that the fourth switching transistor T5 is turned on, the first pixel power voltage ELVDD may be applied to the first electrode of the driving transistor T1. In one embodiment, the first pixel power voltage ELVDD may be a high potential pixel driving voltage.

The fifth switching transistor T6 may include the gate electrode connected to the emission control line ECL, the first electrode connected to the second electrode of the driving transistor T1, and the second electrode connected to the light emitting element EL. The fifth switching transistor T6 may be turned on by the emission control signal supplied to the emission control line ECL to connect the driving transistor T1 to the light emitting element EL. In case that both the fourth switching transistor T5 and the fifth switching transistor T6 are turned on, a driving current having a magnitude corresponding to the voltage (e.g., the voltage of the first node N1) of the gate electrode of the driving transistor T1 may flow to the light emitting element EL.

The sixth switching transistor T7 may include a gate electrode connected to the fourth scan line SL4, a first electrode connected to the first electrode (e.g., an anode electrode) of the light emitting element EL, and a second electrode connected to the second initialization power line VIL2. The sixth switching transistor T7 may be turned on by the fourth scan signal supplied to the fourth scan line SL4 to connect the first electrode of the light emitting element EL to the second initialization power line VIL2. The fourth scan signal and the first scan signal may be a same signal or different signals. In case that the sixth switching transistor T7 is turned on, a second initialization voltage VINT2 (e.g., an anode initialization voltage) of the second initialization power line VIL2 may be applied to the first electrode of the light emitting element EL.

The seventh switching transistor T8 may include a gate electrode connected to the fourth scan line SL4, a first electrode connected to the bias power line VOBL, and a second electrode connected to the first electrode of the driving transistor T1. The seventh switching transistor T8 may be turned on by the fourth scan signal supplied to the fourth scan line SL4 to connect the first electrode of the driving transistor T1 to the bias power line VOBL. In case that the seventh switching transistor T8 is turned on, the bias voltage VOBS supplied to the bias power line VOBL may be applied to the first electrode of the driving transistor T1. In one embodiment, the bias voltage VOBS may have a voltage level suitable for compensating for the hysteresis characteristic of the driving transistor T1. As the seventh switching transistor T8 is turned on, the first electrode of the driving transistor T1 may be initialized to the bias voltage VOBS.

The storage capacitor Cst may be connected between the gate electrode of the driving transistor T1 (or the first node N1) and the first pixel power line VDL. The storage capacitor Cst may be charged with a voltage corresponding to the voltage of the data signal applied to the gate electrode of the driving transistor T1.

The active layer (e.g., a semiconductor pattern including a channel region) of each of the pixel transistors PXT may include a semiconductor material that is one of polysilicon, amorphous silicon, and an oxide semiconductor. In one embodiment, some of the pixel transistors PXT and others of the pixel transistors PXT may be formed of transistors of different conductivity types. Some of the pixel transistors PXT and others of the pixel transistors PXT may include different types of semiconductor materials.

For example, the driving transistor T1 and the first, fourth, fifth, sixth, and seventh switching transistors T2, T5, T6, T7, and T8 may be formed of P-type transistors (e.g., P-type polysilicon transistors) including active layers made of polysilicon, and the second and third switching transistors T3 and T4 may be formed of N-type transistors (e.g., N-type oxide transistors) including active layers made of an oxide semiconductor. In one embodiment, the active layers made of polysilicon and the active layers made of an oxide semiconductor may be disposed on different layers on the substrate 110 of the display panel 100.

The light emitting element EL may be connected between the pixel circuit PXC and the second pixel power line VSL. A second pixel power voltage ELVSS may be applied to the second pixel power line VSL. In one embodiment, the second pixel power voltage ELVSS may be a low potential pixel driving voltage. The light emitting element EL may emit light corresponding to the driving current supplied from the pixel circuit PXC.

In one embodiment, the pixel PX may include a single light emitting element EL, but the disclosure is not limited thereto. In another embodiment, the pixel PX may include at least two light emitting elements EL.

The light emitting element EL may be an organic light emitting diode, but the disclosure is not limited thereto. For example, the light emitting element EL may be an inorganic light emitting element, a quantum dot light emitting element, or another type of light emitting element.

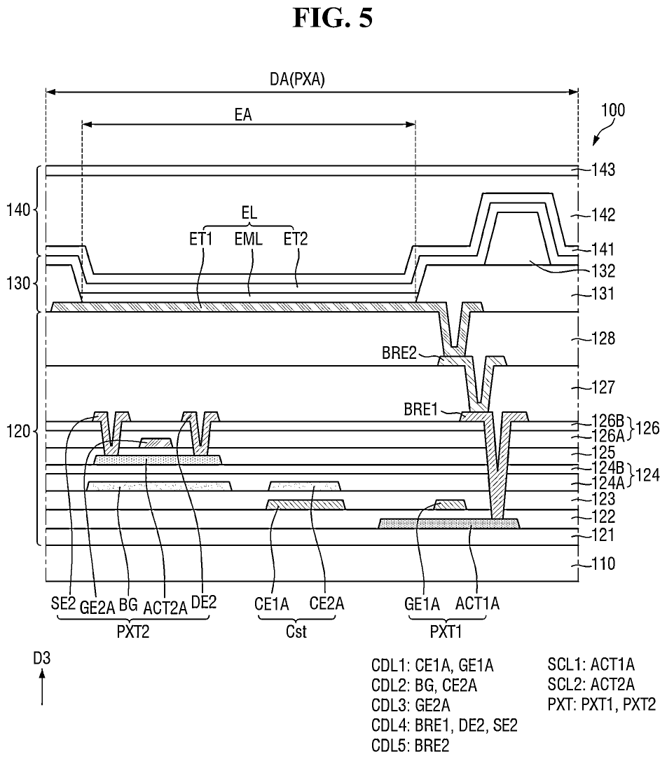

FIG. 5 is a schematic cross-sectional view illustrating the display panel 100 according to one embodiment. For example, FIG. 5 schematically illustrates a cross section of the display panel 100 in a part of the display area DA corresponding to a pixel area PXA in which one pixel PX is positioned.

Referring to FIG. 5 in addition to FIGS. 1 to 4, the display panel 100 may include the substrate 110, and a circuit layer 120, a light emitting element layer 130, and an encapsulation layer 140 disposed on the substrate 110. In one embodiment, the circuit layer 120, the light emitting element layer 130, and the encapsulation layer 140 may be sequentially arranged on the substrate 110 in the third direction D3. In describing the embodiments, the circuit layer 120 and the light emitting element layer 130 are separately described, but the disclosure is not limited thereto. For example, the circuit layer 120 and the light emitting element layer 130 may be integral with each other.

The substrate 110, which is a base member for forming the display panel 100, may be a rigid or flexible substrate (or film). In one embodiment, the substrate 110 may include an insulating material such as glass and may have rigid characteristics. In another embodiment, the substrate 110 may include polyimide or another insulating material and may have flexible characteristics so that it can be deformed to be bent, folded, or rolled. The type and/or material of the substrate 110 may change depending on embodiments.

The substrate 110 may include the display area DA and the non-display area NA. The display area DA may include the pixel area PXA where the pixels PX are provided. The non-display area NA may include a driving circuit area where the first driving circuit DRV or the like is provided.

The circuit layer 120 may include the pixel circuits PXC and wires provided in the pixels PX. For example, the circuit layer 120 may include wires (for example, the pixel power lines PL) connected to the pixels PX and circuit elements (for example, the pixel transistors PXT and the storage capacitor Cst of FIG. 4) constituting the pixel circuit PXC of each of the pixels PX, the scan lines SL, the emission control lines ECL, and the data lines DL. In one embodiment, the circuit layer 120 may further include circuit elements constituting the first driving circuit DRV, and wires connected to the first driving circuit DRV. In one embodiment, the circuit layer 120 may be formed entirely on a surface of the substrate 110.

FIG. 5 schematically illustrates, as elements that may be provided in the circuit layer 120 in the display area DA, a first pixel transistor PXT1, a second pixel transistor PXT2, and a storage capacitor Cst that are provided in the pixel area PXA of each pixel PX according to an embodiment. In one embodiment, the first pixel transistor PXT1 may represent first type transistors (e.g., P-type polysilicon transistors) including a first semiconductor material (e.g., polysilicon) among the pixel transistors PXT constituting each pixel circuit PXC. For example, the first pixel transistor PXT1 may be one of the driving transistor T1 and the first, fourth, fifth, sixth and/or seventh switching transistors T2, T5, T6, T7, and T8. FIG. 5 schematically illustrates, as the first pixel transistor PXT1, a transistor (e.g., the fifth switching transistor T6 of FIG. 4) connected to the light emitting element EL through at least one bridge electrode among the first type transistors. In one embodiment, the second pixel transistor PXT2 may represent second type transistors (e.g., N-type oxide transistors) including a second semiconductor material (e.g., oxide semiconductor) among the pixel transistors PXT. For example, the second pixel transistor PXT2 may be one of the second and third switching transistors T3 and T4.

Cross sections of the pixels PX may be variously changed according to each of the pixels PX and the type and/or structure of the display panel 100 including the pixel PX. For example, the positions and formation order of the first pixel transistor PXT1, the second pixel transistor PXT2, and the storage capacitor Cst may vary depending on embodiments.

The circuit layer 120 may include semiconductor layers for forming circuit elements, wires, or the like, conductive layers, and insulating layers disposed between and/or around the semiconductor layers and the conductive layers. For example, the circuit layer 120 may include a first semiconductor layer SCL1 (e.g., a polysilicon semiconductor layer), a first insulating layer 122 (e.g., a first inorganic insulating layer), a first conductive layer CDL1 (e.g., a first gate conductive layer), a second insulating layer 123 (e.g., a second inorganic insulating layer), a second conductive layer CDL2 (e.g., a second gate conductive layer), a third insulating layer 124 (e.g., a third inorganic insulating layer), a second semiconductor layer SCL2 (e.g., an oxide semiconductor layer), a fourth insulating layer 125 (e.g., a fourth inorganic insulating layer), a third conductive layer CDL3 (e.g., a third gate conductive layer), a fifth insulating layer 126 (e.g., a fifth inorganic insulating layer), a fourth conductive layer CDL4 (e.g., a first source-drain conductive layer or a first data conductive layer), and a sixth insulating layer 127 (e.g., a first organic insulating layer) sequentially disposed on the substrate 110 in the third direction D3.

In one embodiment, the circuit layer 120 may further include at least one conductive layer and at least one insulating layer disposed on the sixth insulating layer 127. For example, the circuit layer 120 may further include a fifth conductive layer CDL5 (e.g., a second source-drain conductive layer or a second data conductive layer) and a seventh insulating layer 128 (e.g., a second organic insulating layer) that are sequentially disposed on the sixth insulating layer 127.

In one embodiment, the circuit layer 120 may further include at least one conductive layer and/or at least one insulating layer disposed between the substrate 110 and the first semiconductor layer SCL1. For example, the circuit layer 120 may further include a barrier layer and/or a buffer layer 121 disposed between the substrate 110 and the first semiconductor layer SCL1. Although not shown in FIG. 5, the circuit layer 120 may further include a lower conductive layer (e.g., a bottom metal layer) disposed between the substrate 110 and the buffer layer 121.

The buffer layer 121 may be disposed on the substrate 110. The buffer layer 121 may protect elements disposed on the circuit layer 120 and the light emitting element layer 130 from moisture permeating through the substrate 110 that is susceptible to moisture permeation. The buffer layer 121 may include at least one inorganic layer including or containing an inorganic insulating material (e.g., silicon nitride, silicon oxide, silicon oxynitride, titanium oxide, aluminum oxide, or another inorganic insulating material). The material of the buffer layer 121 may be variously changed according to embodiments.

The pixel transistors PXT including the first pixel transistor PXT1 and the second pixel transistor PXT2, and the storage capacitor Cst may be disposed on the buffer layer 121.

The first pixel transistor PXT1 may include a first active layer ACT1A and a first gate electrode GEIA.

The first active layer ACT1A may be provided and/or disposed in the first semiconductor layer SCL1 on the substrate 110. The first active layer ACT1A may include a first semiconductor material (e.g., polysilicon). In one embodiment, the semiconductor patterns (e.g., active layers of at least one pixel transistor PXT and/or at least one driver transistor) provided and/or disposed in the first semiconductor layer SCL1 may be simultaneously formed using a same material.

The first gate electrode GEIA may overlap a part (e.g., a channel region) of the first active layer ACT1A in a plan view. In one embodiment, the first gate electrode GELA may be provided and/or disposed in the first conductive layer CDL1 on the first insulating layer 122 covering the first semiconductor layer SCL1.

In one embodiment, the first pixel transistor PXT1 may further include a first electrode (e.g., a source electrode) connected to a part (e.g., a source region) of the first active layer ACT1A and a second electrode (e.g., a drain electrode) connected to another part (e.g., a drain region) of the first active layer ACT1A. In another embodiment, the first pixel transistor PXT1 may not include a separate source electrode and/or a separate drain electrode, and the source region and/or the drain region of the first active layer ACT1A may form the source electrode and/or the drain electrode of the first pixel transistor PXT1. FIG. 5 schematically illustrates an embodiment in which the first pixel transistor PXT1 does not include a separate source electrode and a separate drain electrode, and the source region and the drain region of the first active layer ACT1A may function as the source electrode and the drain electrode, respectively. In one embodiment, the first pixel transistor PXT1 may be connected and/or integrally formed with the active layer of at least one other pixel transistor PTX including the active layer provided in the first semiconductor layer SCL1.

The first pixel transistor PXT1 may be connected to another circuit element, wire, and/or light emitting element EL through at least one bridge electrode. For example, the first pixel transistor PXT1 may be connected to the light emitting element EL of the corresponding pixel PX through a first bridge electrode BRE1 and a second bridge electrode BRE2.

The storage capacitor Cst may include a first capacitor electrode CELA and a second capacitor electrode CE2A. The first capacitor electrode CEIA and the second capacitor electrode CE2A may overlap each other in a plan view, and the second insulating layer 123 may be interposed between the first capacitor electrode CEIA and the second capacitor electrode CE2A.

The first capacitor electrode CEIA may be provided and/or disposed in the first conductive layer CDL1. In one embodiment, the first capacitor electrode CEIA may be connected and/or integrally formed with the gate electrode of at least one pixel transistor PTX whose gate electrode is connected to the storage capacitor Cst. For example, the first capacitor electrode CEIA may be connected and/or integrally formed with the gate electrode of the driving transistor T1 of FIG. 4.

The second capacitor electrode CE2A may be provided and/or disposed in the second conductive layer CDL2. In one embodiment, the second conductive layer CDL2 may be provided and/or disposed on the second insulating layer 123 covering the first conductive layer CDL1.

The second pixel transistor PXT2 may include a second active layer ACT2A and a second gate electrode GE2A. In one embodiment, the second pixel transistor PXT2 may further include a bottom electrode BG. In one embodiment, the second pixel transistor PXT2 may further include a source electrode SE2 (also referred to as “second source electrode”) and a drain electrode DE2 (also referred to as “second drain electrode”) that are connected to the second active layer ACT2A.

The bottom electrode BG of the second pixel transistor PXT2 may be disposed under the second active layer ACT2A and overlap at least a part (e.g., at least a part of the second active layer ACT2A, including a channel region overlapping the second gate electrode GE2A) of the second active layer ACT2A in a plan view. In one embodiment, the bottom electrode BG may be provided and/or disposed in the second conductive layer CDL2. In one embodiment, the bottom electrode BG may be connected to the gate electrode (e.g., the second gate electrode GE2A) or the source electrode SE2 of the second pixel transistor PXT2, and may be utilized as a back-gate electrode for adjusting the characteristics of the second pixel transistor PXT2.

The second active layer ACT2A may be provided and/or disposed in the second semiconductor layer SCL2 on the substrate 110. In one embodiment, the second semiconductor layer SCL2 may be provided and/or disposed on the third insulating layer 124 covering the second conductive layer CDL2. The second active layer ACT2A may include a second semiconductor material (e.g., an oxide semiconductor) different from the first semiconductor material. For example, the second active layer ACT2A may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO), or other oxide semiconductors. In one embodiment, the semiconductor patterns (e.g., active layers of at least one pixel transistor PXT and/or at least one driver transistor) provided and/or disposed in the second semiconductor layer SCL2 may be simultaneously formed using a same material.

The second gate electrode GE2A may overlap a part (e.g., a channel region) of the second active layer ACT2A in a plan view. In one embodiment, the second gate electrode GE2A may be provided and/or disposed in the third conductive layer CDL3 on the fourth insulating layer 125 covering the second semiconductor layer SCL2.

The source electrode SE2 and the drain electrode DE2 of the second pixel transistor PXT2 may be provided and/or disposed in the fourth conductive layer CDL4 on the fifth insulating layer 126 covering the third conductive layer CDL3. In another embodiment, the second pixel transistor PXT2 may not include a separate source electrode SE2 and/or a separate drain electrode DE2, and may include a source electrode and/or a drain electrode formed integrally with the source region and/or the drain region of the second active layer ACT2A.

In one embodiment, at least one bridge electrode may be further provided in the fourth conductive layer CDL4. For example, the first bridge electrode BRE1 connected to the first pixel transistor PTX1 may be provided in the fourth conductive layer CDL4.

In one embodiment, the first bridge electrode BRE1 may be connected to the light emitting element EL of the corresponding pixel PX through the second bridge electrode BRE2. In one embodiment, the second bridge electrode BRE2 may be provided and/or disposed in the fifth conductive layer CDL5 on the sixth insulating layer 127 covering the fourth conductive layer CDLA.

The respective electrodes, conductive patterns, and/or wires provided in the conductive layers of the circuit layer 120 may include at least one conductive material. For example, the electrodes, the conductive patterns, and/or the wires provided in each of the first conductive layer CDL1, the second conductive layer CDL2, the third conductive layer CDL3, the fourth conductive layer CDL4, and the fifth conductive layer CDL5 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), the like, and an alloy thereof, or another conductive material. In one embodiment, the electrodes, the conductive patterns, and/or the wires disposed in the same conductive layer may be simultaneously formed using a same conductive material.

In one embodiment, each of the electrodes, conductive patterns, and/or wires provided in the conductive layers of the circuit layer 120 may have a single-layer or multi-layer structure. For example, the electrodes, the conductive patterns, and/or the wires provided in the first conductive layer CDL1, the second conductive layer CDL2, the third conductive layer CDL3, the fourth conductive layer CDL4, and the fifth conductive layer CDL5 may have a single-layer or multi-layer structure.

In one embodiment, each of the electrodes, the conductive patterns, and/or the wires provided in the fourth conductive layer CDL4 and the fifth conductive layer CDL5 may include a metal (e.g., at least one of molybdenum (Mo), aluminum (Al), chromium (Cr), gold (Au), titanium (Ti), nickel (Ni), neodymium (Nd), copper (Cu), the like, and an alloy thereof), and may have a single-layer or multi-layer structure. For example, each of the electrodes, the conductive patterns, and/or the wires provided in the fourth conductive layer CDL4 and the fifth conductive layer CDL5 may be formed in a triple-layer structure of titanium/aluminum/titanium (Ti/Al/Ti). The fourth conductive layer CDL4 and the fifth conductive layer CDL5 may include a same material or may include different materials. Materials of each of the fourth conductive layer CDL4 and the fifth conductive layer CDL5 may be variously changed according to embodiments.

In one embodiment, the circuit layer 120 may include multiple inorganic insulating layers. For example, each of the insulating layers (e.g., the buffer layer 121, the first insulating layer 122, the second insulating layer 123, the third insulating layer 124, the fourth insulating layer 125, and the fifth insulating layer 126) under the fourth conductive layer CDL4 may be a single-layer or multi-layer inorganic insulating layer. Each of the insulating layers (e.g., the buffer layer 121, the first insulating layer 122, the second insulating layer 123, the third insulating layer 124, the fourth insulating layer 125, and the fifth insulating layer 126) may include an inorganic insulating material (e.g., silicon nitride, silicon oxide, silicon oxynitride, titanium oxide, aluminum oxide, or another inorganic insulating material).

The first insulating layer 122 may be disposed on the buffer layer 121 (or the substrate 110). The first insulating layer 122 may cover patterns (e.g., the first active layer ACT1A) provided in the first semiconductor layer SCL1. In one embodiment, the first insulating layer 122 may include a silicon oxide layer including or containing a silicon oxide.

The second insulating layer 123 may be disposed on the first insulating layer 122. The second insulating layer 123 may cover patterns (e.g., the first gate electrode GELA and the first capacitor electrode CEIA) provided in the first conductive layer CDL1. In one embodiment, the second insulating layer 123 may include a silicon nitride layer including or containing silicon nitride or a silicon oxynitride layer including or containing silicon oxynitride.

The third insulating layer 124 may be disposed on the second insulating layer 123. The third insulating layer 124 may cover patterns (e.g., the bottom electrode BG of the second pixel transistor PXT2 and the second capacitor electrode CE2A) provided in the second conductive layer CDL2. In one embodiment, the third insulating layer 124 may include a first layer 124A (e.g., a silicon nitride layer or a silicon oxynitride layer) including or containing silicon nitride or silicon oxynitride, and a second layer 124B (e.g., a silicon oxide layer) including or containing silicon oxide.

The fourth insulating layer 125 may be disposed on the third insulating layer 124. The fourth insulating layer 125 may cover patterns (e.g., the second active layer ACT2A) provided in the second semiconductor layer SCL2. In one embodiment, the fourth insulating layer 125 may include a silicon oxide layer.

The fifth insulating layer 126 may be disposed on the fourth insulating layer 125. The fifth insulating layer 126 may cover patterns (e.g., the second gate electrode GE2A) provided in the third conductive layer CDL3. In one embodiment, the fifth insulating layer 126 may include a first layer 126A (e.g., a silicon oxide layer) including or containing silicon oxide, and a second layer 126B (e.g., a silicon nitride layer or a silicon oxynitride layer) including or containing silicon nitride or silicon oxynitride.

In one embodiment, the circuit layer 120 may further include at least one organic insulating layer. For example, each of the insulating layers (e.g., the sixth insulating layer 127 and the seventh insulating layer 128) on the fourth conductive layer CDL4 may include an organic insulating layer. Each organic insulating layer may include an organic insulating material (e.g., an acryl resin, an epoxy resin, a phenolic resin, a polyamide resin, a polyimide resin, or another organic insulating material).

The sixth insulating layer 127 may be disposed on the fifth insulating layer 126. The sixth insulating layer 127 may cover patterns (e.g., the source electrode SE2 and the drain electrode DE2 of the second pixel transistor PXT2, and the first bridge electrode BRE1) provided in the fourth conductive layer CDL4.

The seventh insulating layer 128 may be disposed on the sixth insulating layer 127. The seventh insulating layer 128 may cover patterns (e.g., the second bridge electrode BRE2) provided in the fifth conductive layer CDL5.

The light emitting element layer 130 may be disposed on the circuit layer 120. For example, the light emitting element layer 130 may be positioned at least in the display area DA, and may be disposed on the seventh insulating layer 128. In an embodiment in which the circuit layer 120 does not include the fifth conductive layer CDL5 and the seventh insulating layer 128, the light emitting element layer 130 may be disposed on the sixth insulating layer 127.

The light emitting element layer 130 may include the light emitting elements EL of the pixels PX. For example, the light emitting element layer 130 may include a pixel defining layer 131 for partitioning the emission area EA of each of the pixels PX and the light emitting element EL disposed in each emission area EA. In one embodiment, the light emitting element layer 130 may further include a spacer 132 disposed on a part of the pixel defining layer 131.

Each light emitting element EL may include a first electrode ET1 (e.g., an anode electrode) located in each emission area EA, and a light emitting layer EML and a second electrode ET2 (e.g., a cathode electrode) that are sequentially disposed on the first electrode ET1. The first electrode ET1 of the light emitting element EL may be connected to at least one pixel transistor PXT included in the corresponding pixel PX.

The first electrode ET1 of the light emitting element EL may be a single-layer or multi-layer electrode including a conductive material. In one embodiment, the first electrode ET1 may include a metallic material having high reflectivity. For example, the first electrode ET1 may have a single-layer structure including molybdenum (Mo), titanium (Ti), copper (Cu), or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In203) and silver (Ag), magnesium (Mg), aluminum (Al), platinum (Pt), lead (Pb), gold (Au), or nickel (Ni).

The light emitting layer EML of the light emitting element EL may include a high molecular material or a low molecular material. Light emitted from the light emitting layer EML may contribute to image display.

The second electrode ET2 of the light emitting element EL may include a conductive material. In one embodiment, the second electrode ET2 may be a common layer formed across the entire display area DA and cover the light emitting layer EML and the pixel defining layer PDL. In one embodiment, the second electrode ET2 may be formed of a transparent conductive material such as ITO, IZO, ZnO, ITZO, or the like capable of transmitting light, or a semi-transmissive conductive material such as magnesium (Mg), silver (Ag), or an alloy of magnesium (Mg) and silver (Ag).

The pixel defining layer 131 may have an opening corresponding to each of the emission areas EA and may surround the emission areas EA in a plan view. For example, the pixel defining layer 131 may cover an edge of the first electrode ET1 of the light emitting element EL and may include an opening exposing the remaining portion of the first electrode ET1 in a plan view. A region where the exposed first electrode ET1 and the light emitting layer EML overlap (or a region including the same) may be defined as an emission area EA of each pixel PX. In one embodiment, the pixel defining layer 131 may include an organic insulating material.

The spacer 132 may be disposed on a part of the pixel defining layer 131. In one embodiment, the spacer 132 may include an organic insulating material. The spacer 132 and the pixel defining layer 131 may include a same material or different materials. The pixel defining layer 131 and the spacer 132 may be sequentially formed through individual mask processes, or may be simultaneously and/or integrally formed using a halftone mask.

The encapsulation layer 140 may be disposed on the light emitting element layer 130. The encapsulation layer 140 may cover the light emitting element layer 130 in the display area DA and may extend to the non-display area NA to be in contact with the circuit layer 120. The encapsulation layer 140 may block the permeation of oxygen or moisture into the light emitting element layer 130, and may reduce electrical and/or physical impacts to the circuit layer 120 and the light emitting element layer 130.

In one embodiment, the encapsulation layer 140 may include a first encapsulation layer 141, a second encapsulation layer 142, and a third encapsulation layer 143 sequentially disposed on the light emitting element layer 130. Each of the first encapsulation layer 141 and the third encapsulation layer 143 may be an inorganic encapsulation layer including or containing an inorganic material. The second encapsulation layer 142 may be an organic encapsulation layer including or containing an organic material.

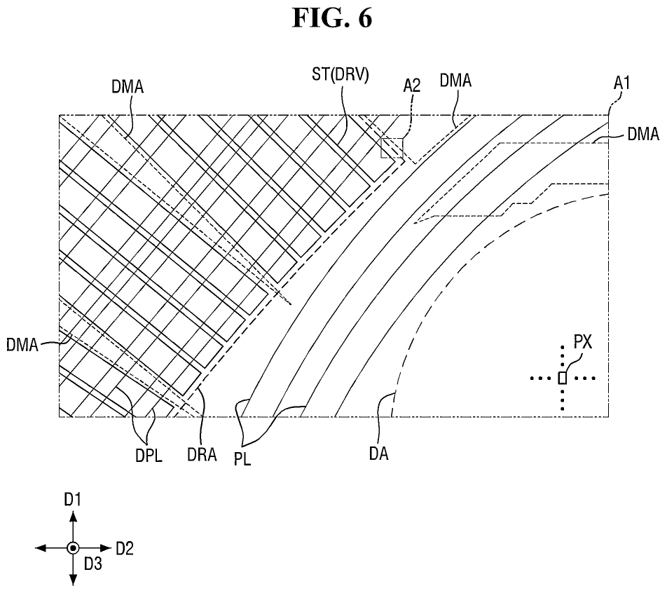

FIG. 6 is a plan view showing a part of the display panel 100 according to one embodiment. For example, FIG. 6 schematically illustrates area A1 of FIG. 3 according to an embodiment.

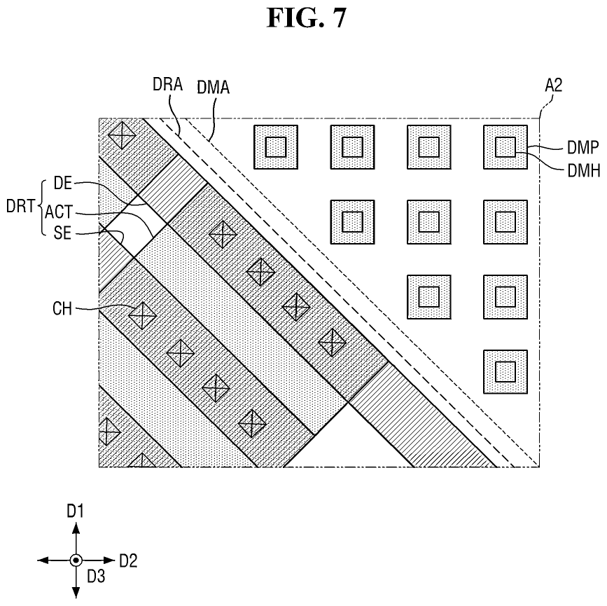

FIG. 7 is a plan view schematically showing a driver transistor DRT and a dummy pattern DMP according to one embodiment. For example, FIG. 7 schematically illustrates area A2 of FIG. 6 according to an embodiment.

Referring to FIGS. 6 and 7 in addition to FIGS. 1 to 5, the non-display area NA may include a driving circuit area DRA and a dummy area DMA disposed adjacent to the display area DA. In one embodiment, the dummy area DMA may be located inside and/or around the display area DA and/or the driving circuit area DRA. For example, the display panel 100 may include at least one dummy area DMA located around the display area DA and/or the driving circuit area DRA, and at least one dummy area DMA located inside the driving circuit area DRA (for example, between some stage circuits ST).

The stage circuits ST of the first driving circuit DRV may be disposed in the driving circuit area DRA. For example, the driving circuit area DRA may include stage areas where the respective stage circuits ST provided in the first driving circuit DRV are disposed.

Each stage circuit ST may include at least one scan stage circuit for generating at least one scan signal, and/or at least one emission stage circuit for generating at least one emission control signal. Each stage circuit ST may include multiple driver transistors DRT and at least one capacitor (e.g., at least one driver capacitor provided at the output terminal of each stage circuit ST). The configuration of each stage circuit ST and the first driving circuit DRV including the same is not particularly limited, and may be variously changed depending on embodiments.

FIG. 7 illustrates only the schematic shape of the driver transistor DRT with respect to patterns disposed in one semiconductor layer (e.g., the first semiconductor layer SCL1) and one conductive layer (e.g., the fourth conductive layer CDL4) that are provided in the circuit layer 120. However, the disclosure is not limited thereto, and the shape, structure, and/or configuration of the driver transistor DRT may be variously changed depending on embodiments.

In one embodiment, the driver transistor DRT may include the active layer ACT, and the source electrode SE and the drain electrode DE connected to different parts of the active layer ACT. The driver transistor DRT may further include a gate electrode overlapping the active layer ACT in a plan view.

In one embodiment, the source electrode SE of the driver transistor DRT may be disposed on a part (e.g., the source region) of the active layer ACT, and may be connected to a part of the active layer ACT through at least one contact hole CH. In one embodiment, the drain electrode DE of the driver transistor DRT may be disposed on another part (e.g., the drain region) of the active layer ACT, and may be connected to another part of the active layer ACT through at least one other contact hole CH.

In one embodiment, the stage circuits ST may be disposed in the display panel 100 to correspond to the shape of the display area DA and/or the display panel 100. For example, the stage circuits ST located adjacent to the corner of the display area DA and/or the main region MA may be disposed in the respective stage areas extending in a diagonal direction inclined with respect to the first direction DR1 and the second direction DR2. In one embodiment, the dummy area DMA may be disposed in the space between the stage circuits ST extending in different directions and/or at different angles adjacent to the corner portion of the display area DA and/or the main region MA.

At least one dummy pattern DMP may be disposed in each dummy area DMA. In one embodiment, the dummy patterns DMP may be disposed with a substantially uniform size and/or gap in each dummy area DMA.

In one embodiment, the dummy area DMA may include patterns formed on the display panel 100, for example, patterns (e.g., active layers and electrodes) forming circuit elements (e.g., transistors and capacitors) located in the display area DA and/or the driving circuit area DRA, and the dummy patterns DMP for making the density of the wires located inside and/or around the display area DA and/or the driving circuit area DRA more uniform. For example, the dummy patterns DMP may be located around circuit elements and wires formed in the circuit layer 120 of the display panel 100, and may be appropriately disposed in an empty space where the circuit elements and wires are not disposed. In one embodiment, the dummy pattern DMP located at the edge of the dummy area DMA may be adjacent to at least one neighboring pixel transistor PXT or at least one neighboring driver transistor, and may be disposed in the first semiconductor layer SCL1 while being spaced apart from the pixel transistor PXT or the driver transistor.

Although not shown in FIG. 6, the scan lines SL and/or the emission control lines ECL may be disposed between the stage circuits ST and the pixels PX. In one embodiment, the dummy patterns DMP may be appropriately and/or uniformly disposed in other areas except the area where the circuit elements, the scan lines SL, and/or the emission control lines ECL that are disposed in the display area DA and/or the driving circuit area DRA are densely arranged.

By arranging the dummy patterns DMP, the density of the patterns formed on the display panel 100 may become more uniform. Accordingly, the process variation of the respective circuit elements and/or wires may be reduced, and the patterns of the display panel 100 may be appropriately formed in a desired shape and/or size.

In one embodiment, at least one dummy hole DMH corresponding to each dummy pattern DMP may be disposed in each dummy area DMA. In one embodiment, each dummy hole DMH may be disposed on each dummy pattern DMP. The dummy holes DMH may penetrate multiple inorganic insulating layers covering the dummy patterns DMP, thereby exposing a part of each of the dummy patterns DMP. Depending on embodiments, at least one shielding layer and/or connection pattern may be further disposed on the dummy patterns DMP. A detailed description will be given below.

Since the dummy holes DMH are formed, the characteristics of the circuit elements (e.g., transistors) formed on the display panel 100 may become more uniform. For example, since the dummy holes DMH are formed, the circuit elements of the circuit layer 120 may be controlled to have more uniform characteristics by uniformly controlling the dehydrogenation behavior of the organic insulating layer (e.g., the sixth insulating layer 127 of FIG. 5) formed in the circuit layer 120 of the display panel 100.

Power lines may be disposed inside and/or around the display area DA and/or the driving circuit area DRA. For example, the pixel power lines PL for transferring power voltages, e.g., the first pixel power voltage ELVDD, the second pixel power voltage ELVSS, the first initialization voltage VINT1, the second initialization voltage VINT2, and/or the bias voltage VOBS, for driving the pixels PX to the pixels PX may be disposed inside and/or around the display area DA. FIG. 6 shows schematic positions and shapes of two pixel power lines PL, which represent the pixel power lines PL, passing through an area between the display area DA and the driving circuit area DRA. In one embodiment, the two pixel power lines PL may be the first initialization power line VIL1 and the second initialization power line VIL2, but the disclosure is not limited thereto. In one embodiment, each of the two pixel power lines PL may be disposed in the fourth conductive layer CDLA or the fifth conductive layer CDL5 of the circuit layer 120. For example, the two pixel power lines PL may be spaced apart from each other in the fifth conductive layer CDL5 of the circuit layer 120.

Driver power lines DPL for supplying power voltages, e.g., a high potential first driver power voltage (e.g., a gate high voltage) and a low potential second driver power voltage (e.g., a gate low voltage), for driving the first driving circuit DRV to the stage circuits ST may be disposed inside and/or around the driving circuit area DRA. FIG. 6 shows schematic positions and shapes of multiple (e.g., six) driver power lines DPL passing through the driving circuit area DRA. In one embodiment, some of the driver power lines DPL may supply the high potential first driver power voltage to the stage circuits ST, and others of the driver power lines DPL may supply the low potential second driver power voltage to the stage circuits ST. In one embodiment, each of the driver power lines DPL may be disposed in the fourth conductive layer CDL4 or the fifth conductive layer CDL5 of the circuit layer 120. The types, numbers, positions, and/or shapes of the pixel power lines PL and the driver power lines DPL that are provided in the display panel 100 may be variously changed depending on embodiments.

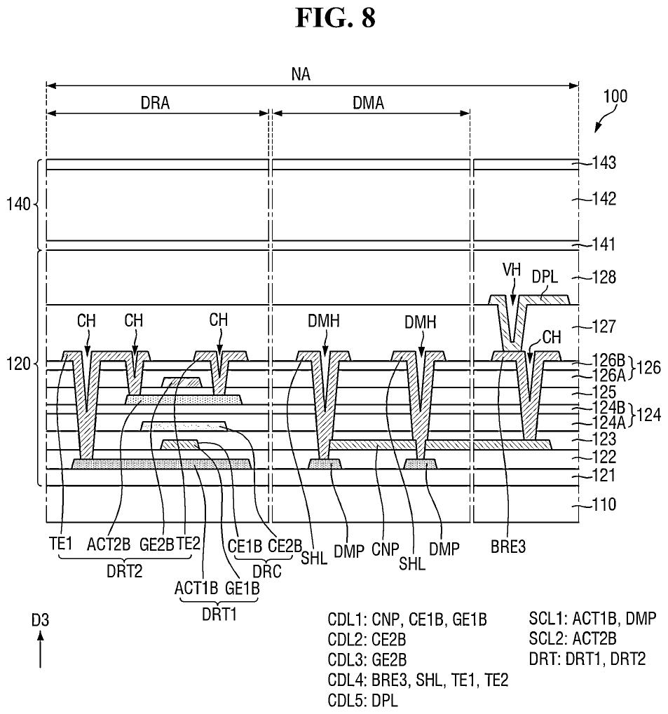

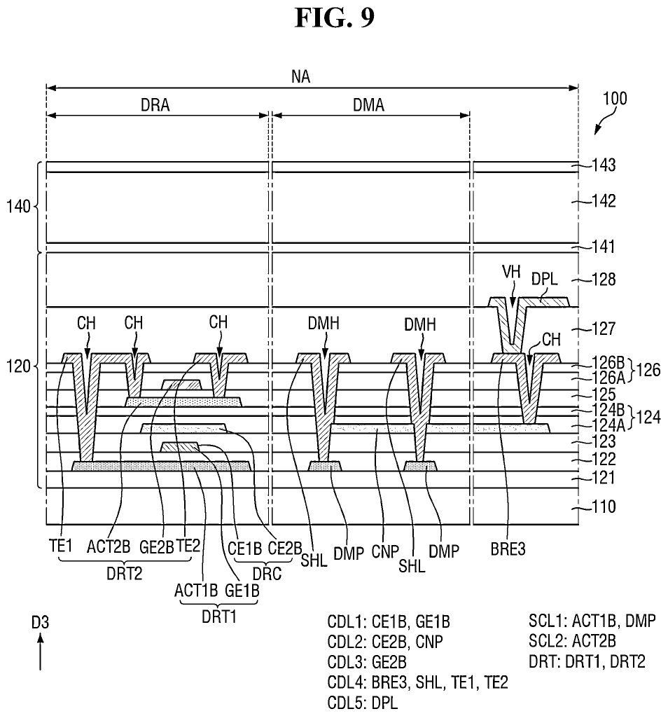

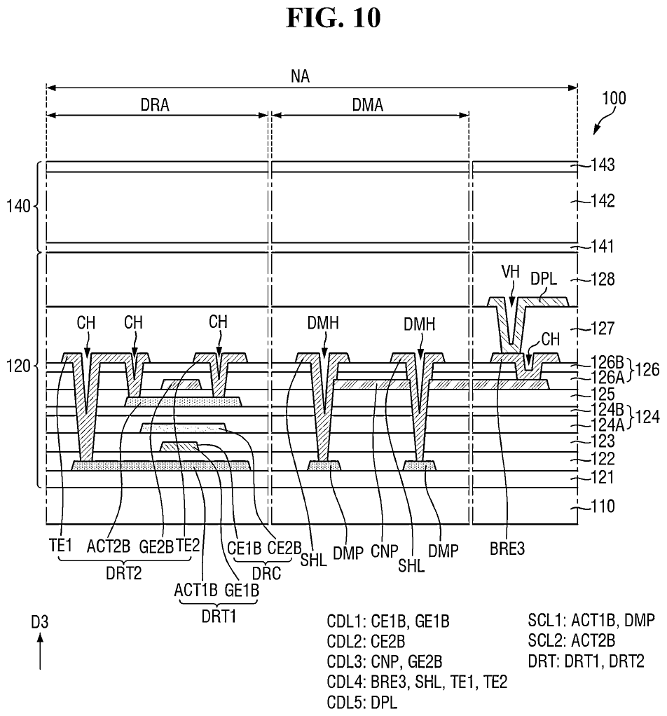

FIG. 8 is a schematic cross-sectional view illustrating the display panel 100 according to one embodiment. FIG. 9 is a schematic cross-sectional view illustrating the display panel 100 according to one embodiment. FIG. 10 is a schematic cross-sectional view illustrating the display panel 100 according to one embodiment. For example, FIGS. 8 to 10 schematically show the cross section of the display panel 100 in a part of the non-display area NA including a part of each of the driving circuit area DRA and the dummy area DMA. FIGS. 8 to 10 show different embodiments in relation to a connection pattern CNP connected to shielding layers SHL of the dummy area DMA.

Referring to FIGS. 8 to 10 in addition to FIGS. 1 to 7, the circuit layer 120 may further include circuit elements (e.g., a driver capacitor DRC and the driver transistors DRT of each stage circuit ST) constituting the stage circuits ST of the first driving circuit DRV, and the dummy patterns DMP located adjacent to the circuit elements. In one embodiment, the dummy patterns DMP may also be disposed adjacent to the pixels PX (e.g., the pixels PX located at the edge of the display area DA). At least one power line (e.g., at least one driver power line DPL and/or at least one pixel power line PL) may be disposed around the dummy patterns DMP.

FIGS. 8 to 10 schematically illustrate, as elements that may be provided in the circuit layer 120 in the driving circuit area DRA, a first driver transistor DRT1, the driver capacitor DRC, and a second driver transistor DRT2 that are provided in the stage area of each stage circuit ST according to an embodiment. Further, FIGS. 8 to 10 schematically illustrate, as elements that may be provided in the circuit layer 120 in the dummy area DMA, two dummy patterns DMP adjacent to each other and the dummy holes DMH and the shielding layers SHL that are disposed on the dummy patterns DMP according to an embodiment. FIGS. 8 to 10 also schematically illustrate, as power lines that may be disposed adjacent to the dummy patterns DMP, a driver power line DPL provided in the fifth conductive layer CDL5 according to an embodiment.

In one embodiment, the first driver transistor DRT1 (also referred to as “first transistor”) may be a first type transistor (e.g., P-type polysilicon transistors) including the first semiconductor material (e.g., polysilicon) among the driver transistors DRT constituting each stage circuit ST. In one embodiment, the second driver transistor DRT2 (also referred to as “second transistor”) may be a second type transistor (e.g., N-type oxide transistors) including the second semiconductor material (e.g., an oxide semiconductor) among the driver transistors DRT. In one embodiment, the first driving circuit DRV may be formed as a CMOS circuit including the first driver transistor DRT1 and the second driver transistor DRT2.

The first driver transistor DRT1 may include a first active layer ACT1B and a first gate electrode GEIB.

The first active layer ACT1B may be provided and/or disposed in the first semiconductor layer SCL1 on the substrate 110. The first active layer ACT1B may include a first semiconductor material.

The first gate electrode GELB may overlap a part (e.g., a channel region) of the first active layer ACT1B in a plan view. In one embodiment, the first gate electrode GELB may be provided and/or disposed in the first conductive layer CDL1.

In one embodiment, the first driver transistor DRT1 may further include a first electrode (e.g., a source electrode or a drain electrode integrally connected to a first electrode TE1 of the second driver transistor DRT2) connected to a part of the first active layer ACT1B. In one embodiment, the first driver transistor DRT1 may further include a second electrode (e.g., a drain electrode or a source electrode provided in the fourth conductive layer CDL4) connected to another part of the first active layer ACT1B. In another embodiment, the first driver transistor DRT1 may not include a separate source electrode and/or a separate drain electrode, and the source region and/or the drain region of the first active layer ACT1B may form the source electrode and/or the drain electrode of the first driver transistor DRT1. In one embodiment, the first driver transistor DRT1 may be connected and/or integrally formed with the active layer of at least one other first driver transistor DRT1 including each active layer provided in the first semiconductor layer SCL1.

The driver capacitor DRC may include a first capacitor electrode CE1B and a second capacitor electrode CE2B. The first capacitor electrode CE1B and the second capacitor electrode CE2B may overlap each other in a plan view, and the second insulating layer 123 may be interposed between the first capacitor electrode CE1B and the second capacitor electrode CE2B.

The first capacitor electrode CE1B may be provided and/or disposed in the first conductive layer CDL1. In one embodiment, the first capacitor electrode CE1B may be connected and/or integrally formed with the first gate electrode GELB of at least one first driver transistor DRT1.

The second capacitor electrode CE2B may be provided and/or disposed in the second conductive layer CDL2. In one embodiment, the second conductive layer CDL2 may be provided and/or disposed on the second insulating layer 123.

The second driver transistor DRT2 may include a second active layer ACT2B and a second gate electrode GE2B. In one embodiment, the second driver transistor DRT2 may include a bottom electrode provided in the second conductive layer CDL2 or the like, but the disclosure is not limited thereto. In one embodiment, the second driver transistor DRT2 may further include the first electrode TE1 and a second electrode TE2 that are connected to different parts of the second active layer ACT2B.

The first electrode TE1 may be one of the source electrode and the drain electrode of the second driver transistor DRT2, and the second electrode TE2 may be another one of the source electrode and the drain electrode of the second driver transistor DRT2. For example, the first electrode TE1 may be connected to one of the source region and the drain region of the second active layer ACT2B through at least one contact hole CH penetrating the fourth and fifth insulating layers 125 and 126, and the second electrode TE2 may be connected to another one of the source region and the drain region of the second active layer ACT2B through at least one other contact hole CH penetrating the fourth and fifth insulating layers 125 and 126. In one embodiment, the first electrode TE1 may be connected to the source region or the drain region of the first active layer ACT1B provided in the first driver transistor DRT1 through at least one contact hole CH penetrating the first, second, third, fourth, and fifth insulating layers 122, 123, 124, 125, and 126.

The second active layer ACT2B may be provided and/or disposed in the second semiconductor layer SCL2. The second active layer ACT2B may include a second semiconductor material (e.g., an oxide semiconductor) that is different from the first semiconductor material. For example, the second active layer ACT2B may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), and the like.

The second gate electrode GE2B may overlap a part (e.g., a channel region) of the second active layer ACT2B in a plan view. In one embodiment, the second gate electrode GE2B may be provided and/or disposed in the third conductive layer CDL3.

The first electrode TE1 and the second electrode TE2 of the second driver transistor DRT2 may be provided and/or disposed in the fourth conductive layer CDL4. In one embodiment, the second driver transistor DRT2 may not include a separate first electrode TE1 and/or a separate second electrode TE2, and may include a source electrode and/or a drain electrode that are formed integrally with the source region and/or the drain region of the second active layer ACT2B.

The dummy patterns DMP may be disposed in the first semiconductor layer SCL1. For example, each dummy pattern DMP may be a semiconductor pattern including a first semiconductor material.

Each dummy pattern DMP may be spaced apart from the driver transistors DRT and the pixel transistors PXT. For example, each dummy pattern DMP may be disposed in the first semiconductor layer SCL1 while being spaced apart from a neighboring first active layer ACT1B of the first driver transistor DRT1 and/or the first active layer ACT1A of a neighboring first pixel transistor PXT1.

The first active layer ACT1B and the first gate electrode GEIB of the first driver transistor DRT1, the first capacitor electrode CE1B and the second capacitor electrode CE2B of the driver capacitor DRC, the second active layer ACT2B and the second gate electrode GE2B of the second driver transistor DRT2, and the dummy patterns DMP may be covered with inorganic insulating layers provided in the circuit layer 120. For example, the first active layer ACT1B and the first gate electrode GEIB, the first capacitor electrode CE1B and the second capacitor electrode CE2B, the second active layer ACT2B and the second gate electrode GE2B, and the dummy patterns DMP may be covered with the first, second, third, fourth, and fifth insulating layers 122, 123, 124, 125, and 126.

The dummy holes DMH may be disposed on the dummy patterns DMP. The dummy holes DMH may penetrate the inorganic insulating layers covering the dummy patterns DMP on the respective dummy patterns DMP to expose a part of each of the respective dummy patterns DMP. For example, the dummy holes DMH may be formed on the respective dummy patterns DMP and penetrate the first, second, third, fourth, and fifth insulating layers 122, 123, 124, 125, and 126.

The shielding layers SHL may be disposed on the dummy patterns DMP. In one embodiment, the shielding layers SHL may be provided in the fourth conductive layer CDL4 together with the first electrode TE1 and the second electrode TE2 of the second driver transistor DRT2, and may be disposed inside at least the respective dummy holes DMH. For example, each shielding layer SHL may be disposed inside and around the dummy hole DMH disposed on each dummy pattern DMP, and may cover the side surfaces of the inorganic insulating layers exposed by the dummy hole DMH. Each shielding layer SHL may partially or completely fill the inside of each dummy hole DMH.

In one embodiment, the shielding layers SHL disposed on the dummy patterns DMP may be separated from each other, but the disclosure is not limited thereto. For example, the shielding layers SHL disposed on at least two dummy patterns DMP may be formed integrally with each other to form substantially one pattern.

In one embodiment, each shielding layer SHL may be a single-layer or multi-layer conductive pattern including or containing a metal. For example, the shielding layers SHL may be formed simultaneously. For example, the shielding layers SHL and the first electrode TE1 and the second electrode TE2 of the second driver transistor DRT2 may include a same conductive material. In one embodiment, each of the shielding layers SHL, and the first electrode TE1 and the second electrode TE2 of the second driver transistor DRT2 may be a metal pattern formed in a triple-layer structure of titanium/aluminum/titanium (Ti/Al/Ti).

In one embodiment, each shielding layer SHL may be connected to a neighboring power line. For example, each shielding layer SHL may be connected to the power line (e.g., the driver power line DPL or the pixel power line PL) provided in the fourth conductive layer CDLA or the fifth conductive layer CDL5 disposed on the inorganic insulating layers of the circuit layer 120. By connecting the conductive shielding layers SHL to the power line to which a constant voltage is applied, the operation of the display panel 100 may be stabilized.

In one embodiment, the display panel 100 may further include at least one connection pattern CNP that connects at least one shielding layer SHL to a neighboring power line. In one embodiment, the connection pattern CNP may be located in the conductive layer between the first semiconductor layer SCL1 where the dummy patterns DMP are disposed and the fourth conductive layer CDL4 where the shielding layers SHL are disposed. For example, the connection pattern CNP may be provided in the first conductive layer CDL1, the second conductive layer CDL2, or the third conductive layer CDL3 as shown in FIGS. 8, 9, and 10, respectively. In another embodiment, the connection pattern CNP may be formed of multi-layer patterns provided in at least two conductive layers among the first conductive layer CDL1, the second conductive layer CDL2, and the third conductive layer CDL3. In one embodiment, in consideration of the patterns disposed in each conductive layer of the area where the respective dummy patterns DMP are located, the conductive layer where the connection patterns CNP are disposed may be selected for each dummy area DMA, or for each sub-region in each dummy area DMA.

In one embodiment, the connection pattern CNP may be connected to a power line (e.g., the driver power line DPL of FIGS. 8 to 10) adjacent to the dummy patterns DMP through at least one bridge electrode. For example, the connection pattern CNP may be connected to a power line provided in the fifth conductive layer CDL5 through a third bridge electrode BRE3 provided in the fourth conductive layer CDL4. The third bridge electrode BRE3 may be connected to the connection pattern CNP through at least one contact hole CH formed in the inorganic insulating layers covering the connection pattern CNP. The third bridge electrode BRE3 may be connected to a power line (e.g., the driver power line DPL or the pixel power line PL) of the fifth conductive layer CDL5 through at least one via hole VH formed in the sixth insulating layer 127 covering the third bridge electrode BRE3.

In another embodiment, the connection pattern CNP may be connected (e.g., directly connected) to the power line adjacent to the dummy patterns DMP. For example, the connection pattern CNP may be connected to a power line provided in the fourth conductive layer CDL4 without being through a separate bridge electrode.

The circuit elements of the driving circuit area DRA and the patterns of the dummy area DMA may be covered with at least one organic insulating layer. For example, the driver transistors DRT, the driver capacitors DRC, the dummy patterns DMP, and the shielding layers SHL may be covered with the sixth insulating layer 127 and/or the seventh insulating layer 128 disposed on the fourth conductive layer CDLA.

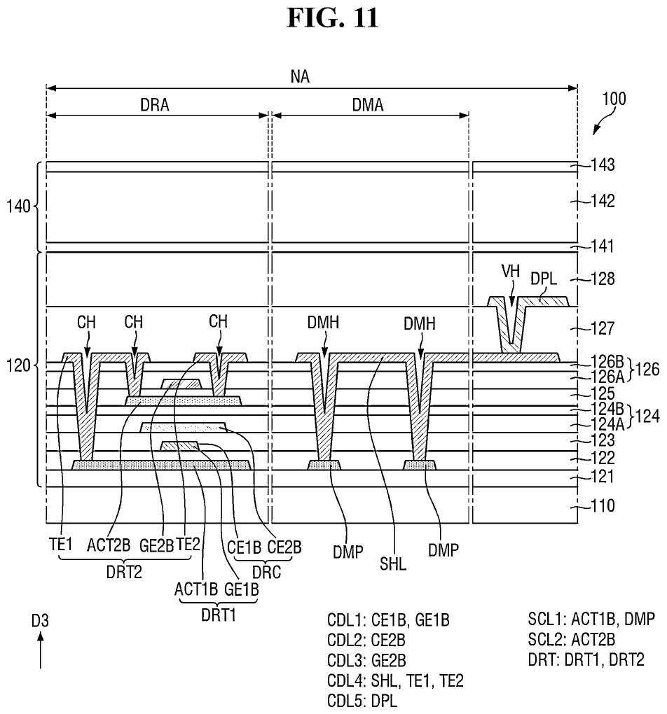

FIG. 11 is a schematic cross-sectional view illustrating the display panel 100 according to one embodiment. For example, FIG. 11 schematically shows an embodiment that is different from the embodiments of FIGS. 8 to 10 in relation to the connection structure of the shielding layer SHL and the power line.

Referring to FIG. 11 in addition to FIGS. 1 to 10, at least one shielding layer SHL may be connected (e.g., directly connected) to a neighboring power line (e.g., the driver power line DPL or the pixel power line PL) without being through a separate connection pattern. For example, at least one shielding layer SHL may extend to an area where a neighboring power line is disposed to overlap the power line, and may be connected (e.g., directly connected) to the power line, and the display panel 100 may not include a separate connection pattern for connecting the shielding layer SHL to the power line. In one embodiment, the shielding layer SHL may be disposed in the fourth conductive layer CDL4, and may be connected to the power line disposed in the fifth conductive layer CDL5 through at least one via hole VH penetrating the sixth insulating layer 127. In another embodiment, the shielding layer SHL may be formed integrally with the power line disposed in the fourth conductive layer CDL4.

In one embodiment, at least two shielding layers SHL adjacent to each other may be formed integrally. For example, the at least two shielding layers SHL may be formed as substantially one pattern.

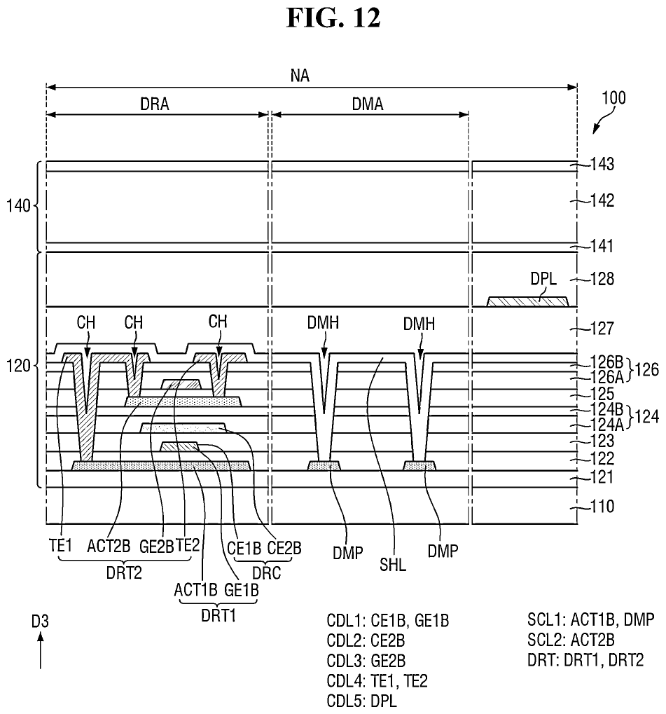

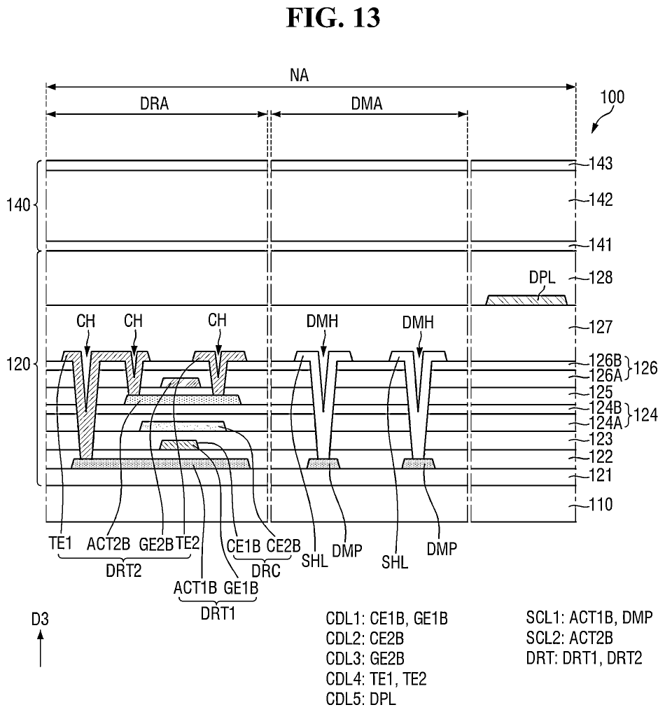

FIG. 12 is a schematic cross-sectional view illustrating the display panel 100 according to one embodiment. FIG. 13 is a schematic cross-sectional view illustrating the display panel 100 according to one embodiment. For example, FIGS. 12 and 13 schematically show embodiments that are different from the embodiments of FIGS. 8 to 11 in relation to the shielding layer SHL.

Referring to FIGS. 12 and 13 in addition to FIGS. 1 to 11, the shielding layer SHL may be an inorganic insulating layer entirely or partially disposed on the fifth insulating layer 126. For example, as shown in FIG. 12, the shielding layer SHL may be entirely disposed between the fifth insulating layer 126 and the sixth insulating layer 127, and may cover the patterns provided in the fourth conductive layer CDL4. In another embodiment, the shielding layer SHL may be partially disposed on the fifth insulating layer 126 as shown in FIG. 13. For example, the shielding layer SHL may be an insulating pattern disposed only inside and adjacent to each dummy hole DMH. The shielding layer SHL may be covered with the sixth insulating layer 127.

In one embodiment, the shielding layer SHL may be a single-layer or multi-layer inorganic insulating layer including or containing nitrogen. For example, the shielding layer SHL may include a silicon nitride layer or a silicon oxynitride layer. In one embodiment, the shielding layer SHL may be a single inorganic insulating layer made of a silicon nitride layer or a silicon oxynitride layer. In another embodiment, the shielding layer SHL may be a multi-layer inorganic insulating layer including a silicon nitride layer, a silicon oxynitride layer, and a silicon oxide layer. By covering the side surfaces of the inorganic insulating layers exposed by the dummy holes DMH with the shielding layer SHL including or containing nitrogen, it is possible to effectively prevent moisture permeation. Accordingly, damage to circuit elements due to outgassing of the organic insulating layer may be prevented. For example, even in case that a transistor (e.g., the second driver transistor DRT2 or the second pixel transistor PXT2) including an oxide semiconductor is disposed adjacent to the dummy holes DMH, deterioration or defects of the transistor due to the out-gassing effect of the organic insulating layer may be prevented by covering the side surfaces of the inorganic insulating layers with the shielding layer SHL.

In one embodiment, the shielding layer SHL may be an inorganic insulating layer having a high nitrogen content. For example, the shielding layer SHL may be an inorganic insulating layer having a high nitrogen content and a refractive index of greater than or equal to about 1.6. Accordingly, neighboring circuit elements may be more reliably protected.

In accordance with the embodiments of FIGS. 8 to 13, the dummy patterns DMP and the dummy holes DMH may be formed adjacent to the pixel PX and/or the first driving circuit DRV including an oxide transistor or the like. For example, the dummy patterns DMP and the dummy holes DMH may be disposed adjacent to the first driving circuit DRV including the first driver transistor DRT1 including the first active layer ACT1B provided in the first semiconductor layer SCL1 and the second driver transistor DRT2 including the second active layer ACT2B provided in the second semiconductor layer SCL2, and/or in a space between the stage circuits ST located in the driving circuit area DRA where the first driving circuit DRV is disposed. Similarly, the dummy patterns DMP and the dummy holes DMH may be disposed adjacent to the pixel circuit PXC of the pixel PX (e.g., the pixels PX located in at least one corner portion of the display area DA) including the first pixel transistor PXT1 including the first active layer ACT1A provided in the first semiconductor layer SCL1 and the second pixel transistor PXT2 including the second active layer ACT2A provided in the second semiconductor layer SCL2. Accordingly, patterns (e.g., circuit elements and/or wires) disposed in the circuit layer 120 of the display panel 100 may be formed more uniformly and accurately. Further, the characteristics of the circuit elements (e.g., the pixel transistors PXT and/or the driver transistors DRT) disposed in the circuit layer 120 may become substantially uniform.

Further, in accordance with the embodiments of FIGS. 8 to 13, the shielding layer SHL covering the side surfaces of the inorganic insulating layers (e.g., the first, second, third, fourth, and fifth insulating layers 122, 123, 124, 125, and 126) exposed by the dummy hole DMH may be formed inside and/or around each dummy hole DMH. In embodiments, the shielding layer SHL may include a material capable of blocking moisture permeation. For example, the shielding layer SHL may be formed of a conductive pattern (or wire) including or containing a metal having a moisture adsorbing property, such as titanium (Ti) or the like, or may be formed of an inorganic insulating layer (or an inorganic insulating pattern) including or containing an inorganic insulating material such as nitrogen. Accordingly, it is possible to prevent or reduce deterioration and/or defects of the circuit elements due to the out-gassing effect of the organic insulating layer (e.g., the sixth insulating layer 127 or the like). For example, since each dummy hole DMH is covered with the shielding layer SHL, the deterioration and/or defects of the circuit element may be prevented even in case that a circuit element such as an oxide transistor is disposed adjacent to the dummy hole DMH. Since a neighboring circuit element may be reliably protected by the shielding layer SHL, the dummy holes DMH may be disposed closer to the circuit elements. Accordingly, the design efficiency of the display panel 100 may be improved. For example, a distance between the circuit elements and the dummy holes DMH may be appropriately shortened, and the area of the non-display area NA may be reduced.

In some embodiments, the shielding layer SHL may be formed of a conductive pattern (or wire), and the shielding layer SHL may be connected to a neighboring power line. For example, each shielding layer SHL may be connected to a neighboring power line through at least one connection pattern CNP and/or the third bridge electrode BRE3, or may be connected (e.g., directly connected) to a neighboring power line without being through a separate connection pattern or a separate bridge electrode. Accordingly, malfunction of the display panel 100 due to the shielding layers SHL may be prevented, and electrical stability of the display panel 100 may be secured.

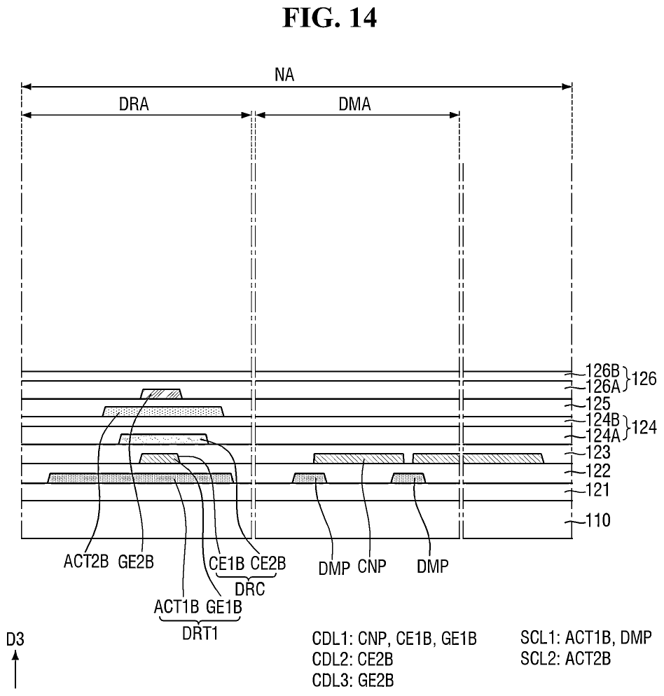

FIGS. 14 to 18 are schematic cross-sectional views illustrating a manufacturing method of the display device 10 according to one embodiment. For example, FIGS. 14 to 18 sequentially show steps of forming the circuit layer 120 including the dummy pattern DMP, the dummy hole DMH, and the shielding layer SHL among steps of manufacturing the display panel 100 of FIG. 8.

FIGS. 14 to 17 schematically show steps of forming patterns of the non-display area NA including the driving circuit area DRA and the dummy area DMA. Among the patterns of the display area DA, the patterns disposed and/or formed in the same layer as the patterns of the non-display area NA may be formed simultaneously with the patterns of the non-display area NA. For example, the first pixel transistor PXT1 and the second pixel transistor PXT2 of FIG. 5 may be formed simultaneously with the first driver transistor DRT1 and the second driver transistor DRT2, respectively.

Referring to FIG. 14 in addition to FIGS. 1 to 13, multiple semiconductor layers, conductive layers, and inorganic insulating layers may be formed on the substrate 110. In one embodiment, the buffer layer 121 may be first formed on the substrate 110, and semiconductor layers and conductive layers, and inorganic insulating layers covering the semiconductor layers and the conductive layers may be formed on the buffer layer 121.

For example, the first semiconductor layer SCL1 including the first active layer ACT1B of the first driver transistor DRT1 and the dummy pattern DMP, the first insulating layer 122 covering the patterns of the first semiconductor layer SCL1, the first conductive layer CDL1 including the first gate electrode GELB of the first driver transistor DRT1 and/or the first capacitor electrode CE1B of the driver capacitor DRC, the second insulating layer 123 covering the patterns of the first conductive layer CDL1, the second conductive layer CDL2 including the second capacitor electrode CE2B of the driver capacitor DRC, the third insulating layer 124 covering the patterns of the second conductive layer CDL2, the second semiconductor layer SCL2 including the second active layer ACT2B of the second driver transistor DRT2, the fourth insulating layer 125 covering the patterns of the second semiconductor layer SCL2, the third conductive layer CDL3 including the second gate electrode GE2B of the second driver transistor DRT2, and the fifth insulating layer 126 covering the patterns of the third conductive layer CDL3 may be sequentially formed on the substrate 110 on which the buffer layer 121 is formed. In one embodiment, in the case of manufacturing the display panel 100 that does not include the second conductive layer CDL2, the step of forming the second conductive layer CDL2 and/or the step of forming the second insulating layer 123 or the third insulating layer 124 may be omitted.

In one embodiment, in the case of manufacturing the display panel 100 including the connection pattern CNP as in the embodiments of FIGS. 8 to 10, the connection pattern CNP may be formed in the step of forming the first conductive layer CDL1, the second conductive layer CDL2, and/or the third conductive layer CDL3. For example, the connection pattern CNP overlapping a part of each dummy pattern DMP in a plan view may be formed in the first conductive layer CDL1.

In one embodiment, in the step of forming each semiconductor layer or each conductive layer, patterns of each semiconductor layer or each conductive layer may be formed in each pixel area PXA of the display area DA. For example, in the step of forming the first semiconductor layer SCL1, the first active layer ACT1A of the first pixel transistor PXT1 may be formed, and in the step of forming the first conductive layer CDL1, the first gate electrode GELB of the first pixel transistor PXT1 and/or the first capacitor electrode CELA of the storage capacitor Cst may be formed. In the same manner, the second capacitor electrode CE2A of the storage capacitor Cst and/or the bottom electrode BG of the second pixel transistor PXT2 may be formed in the step of forming the second conductive layer CDL2, the second active layer ACT2A of the second pixel transistor PXT2 may be formed in the step of forming the second semiconductor layer SCL2, and the second gate electrode GE2A of the second pixel transistor PXT2 may be formed in the step of forming the third conductive layer CDL3.

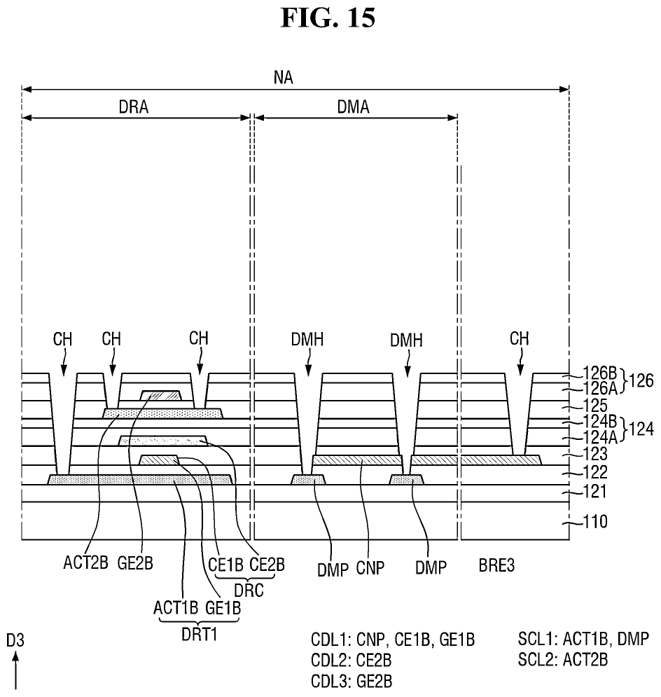

Referring to FIG. 15 in addition to FIGS. 1 to 14, the contact hole CH that exposes a part of the first active layer ACT1B of the first driver transistor DRT1 while penetrating the inorganic insulating layers (e.g., the first, second, third, fourth, and fifth insulating layers 122, 123, 124, 125, and 126) on the first semiconductor layer SCL1, and the dummy holes DMH that expose a part of each of the dummy patterns DMP while penetrating the inorganic insulating layers may be formed. In one embodiment, in the step of forming the dummy holes DMH, the contact holes CH that expose a part of each of the second active layer ACT2B of the second driver transistor DRT2, the first active layer ACT1A of the first pixel transistor PXT1, the second active layer ACT2A of the second pixel transistor PXT2 and/or the connection pattern CNP may be further formed.

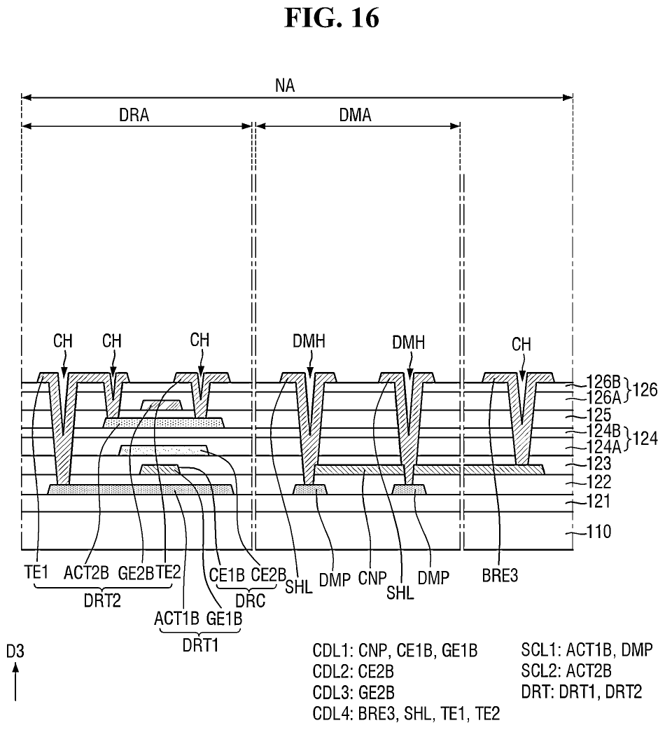

Referring to FIG. 16 in addition to FIGS. 1 to 15, the fourth conductive layer CDL4 including the first electrode TE1 and/or the second electrode TE2 of the second driver transistor DRT2 may be formed on the inorganic insulating layers. The first electrode TE1 of the second driver transistor DRT2 may be connected to a part of the second driver transistor DRT2 through the contact hole CH exposing a part of the second driver transistor DRT2. In the step of forming the fourth conductive layer CDL4, the source electrode SE2 and/or the drain electrode DE2 of the second pixel transistor PXT2, and the first bridge electrode BRE1 may be formed in each pixel area PXA of the display area DA.

In some embodiments, in the step of forming the fourth conductive layer CDL4, the shielding layer SHL may be formed inside the dummy hole DMH. For example, the first electrode TE1 and the second electrode TE2 of the second driver transistor DRT2 and the shielding layer SHL may be formed simultaneously using a conductive material including or containing metal, and the shielding layer SHL may be formed in the fourth conductive layer CDL4. The shielding layer SHL may cover the side surfaces of the inorganic insulating layers exposed by the dummy hole DMH. In one embodiment, the shielding layer SHL may be connected to each dummy pattern DMP and/or the connection pattern CNP in an area where each dummy hole DMH is formed. Since the first electrode TE1 and the second electrode TE2 of the second driver transistor DRT2 and the shielding layer SHL are simultaneously formed, it is possible to simplify the manufacturing process of the display panel 100 and increase the manufacturing efficiency.

In one embodiment, in the case of manufacturing the display panel 100 including the third bridge electrode BRE3 as in the embodiments of FIGS. 8 to 10, the third bridge electrode BRE3 may be formed in the step of forming the fourth conductive layer CDL4. The third bridge electrode BRE3 may be connected to the connection pattern CNP through the contact hole CH formed on the connection pattern CNP.

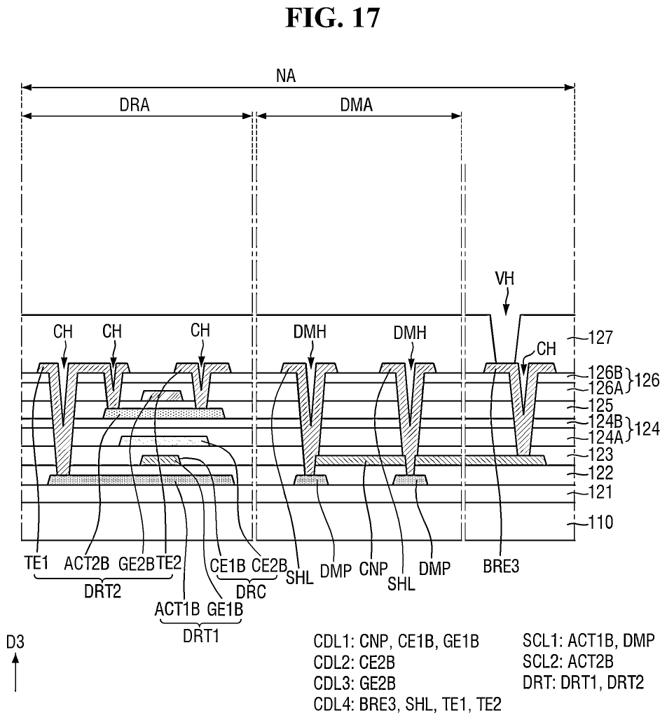

Referring to FIG. 17 in addition to FIGS. 1 to 16, the sixth insulating layer 127 covering the patterns of the fourth conductive layer CDL4 may be formed on the inorganic insulating layers. For example, the sixth insulating layer 127 may cover the first electrode TE1 and the second electrode TE2 of the second driver transistor DRT2, the shielding layer SHL, and/or the third bridge electrode BRE3. In one embodiment, the sixth insulating layer 127 may include an organic insulating layer. In the case of manufacturing the display panel 100 including the third bridge electrode BRE3 as in the embodiments of FIGS. 8 to 10, the via hole VH exposing a part of the third bridge electrode BRE3 while penetrating the sixth insulating layer 127 may be formed. In case that the shielding layer SHL is directly connected to a power line (e.g., the driver power line DPL) disposed thereon as in the embodiment of FIG. 11, the via hole VH exposing a part of the shielding layer SHL while penetrating the sixth insulating layer 127 may be formed.

In one embodiment, in the step of forming the fourth conductive layer CDL4, at least one power line may be further formed on the inorganic insulating layers. Further, the shielding layer SHL on the dummy pattern DMP adjacent to the power line may be formed integrally with the power line.

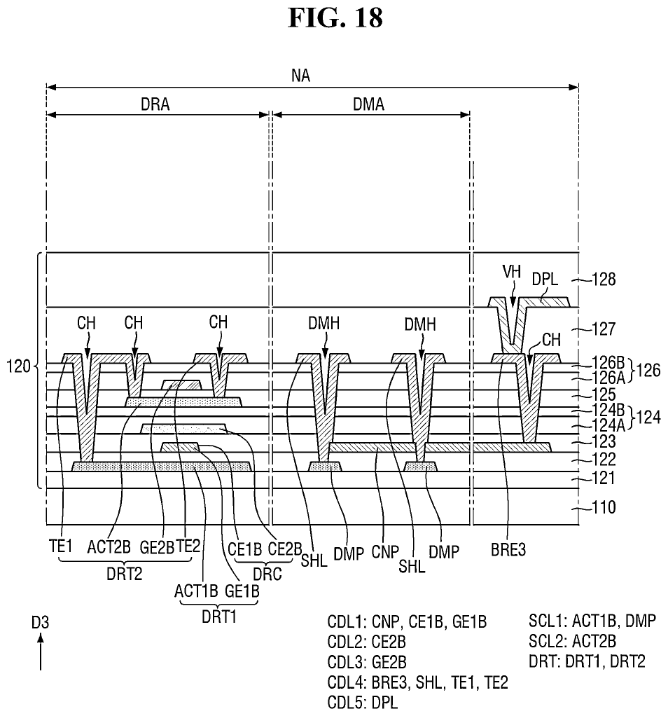

Referring to FIG. 18 in addition to FIGS. 1 to 17, the power line connected to at least one shielding layer SHL may be formed on the inorganic insulating layers and the sixth insulating layer 127. In one embodiment, the power line may be the driver power line DPL and/or the pixel power line PL provided in the fifth conductive layer CDL5. In one embodiment, in the step of forming the fifth conductive layer CDL5, the second bridge electrode BRE2 or the like may be formed in each pixel area PXA of the display area DA.

Thereafter, the seventh insulating layer 128 covering the patterns of the fifth conductive layer CDL5 may be formed. In one embodiment, the seventh insulating layer 128 may include an organic insulating layer.

Through the above-described processes, the circuit layer 120 of the display panel 100 may be formed. In one embodiment, in case that the display panel 100 includes the light emitting element layer 130 and the encapsulation layer 140 shown in FIGS. 5 and 8, the light emitting element layer 130 and the encapsulation layer 140 may be sequentially formed on the circuit layer 120. Through the above-described processes, the display panel 100 and the display device 10 including the same according to embodiments may be manufactured.

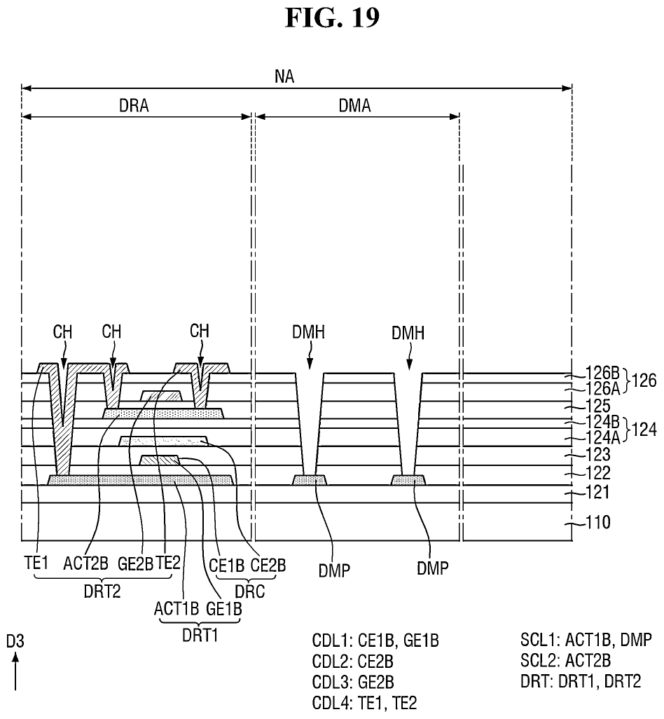

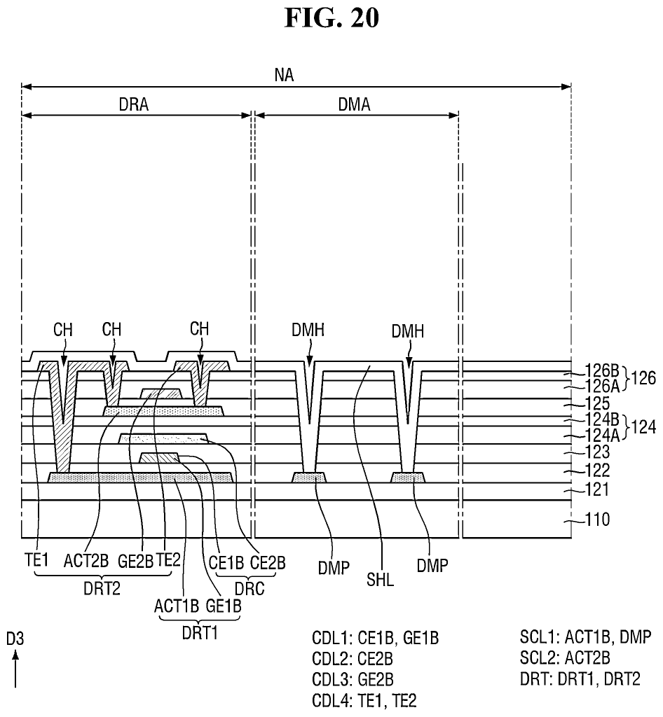

FIGS. 19 and 20 are schematic cross-sectional views illustrating a method for manufacturing the display device 10 according to one embodiment. For example, FIGS. 19 and 20 schematically show steps of forming the dummy hole DMH and the shielding layer SHL among the steps of manufacturing the display panel 100 of FIG. 12.

Referring to FIGS. 19 and 20 in addition to FIGS. 1 to 18, the patterns of the fourth conductive layer CDL4 and the shielding layer SHL may be sequentially formed using different materials. For example, after the first electrode TE1 and the second electrode TE2 of the second driver transistor DRT2 are formed on the inorganic insulating layers of the circuit layer 120 using a conductive material, the shielding layer SHL may be formed on the inorganic insulating layers using an inorganic insulating material including or containing nitrogen. In one embodiment, the shielding layer SHL may be formed to overlap the patterns of the fourth conductive layer CDL4 in a plan view, or may be partially formed only in the dummy area DMA.

Thereafter, the sixth insulating layer 127, the fifth conductive layer CDL5, and the seventh insulating layer 128 shown in FIGS. 12 and 13 may be sequentially formed, thereby forming the circuit layer 120 of the display panel 100. In one embodiment, in case that the display panel 100 includes the light emitting element layer 130 and the encapsulation layer 140 shown in FIGS. 5 and 12, the light emitting element layer 130 and the encapsulation layer 140 may be sequentially formed on the circuit layer 120.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first transistor comprising a first active layer disposed in a first semiconductor layer on a substrate, and a first gate electrode overlapping the first active layer in a plan view;
a second transistor comprising a second active layer disposed in a second semiconductor layer on the substrate, and a second gate electrode overlapping the second active layer in a plan view;
a dummy pattern disposed in the first semiconductor layer and spaced apart from the first active layer;
inorganic insulating layers disposed on the substrate, and covering the first active layer, the dummy pattern, the first gate electrode, the second active layer, and the second gate electrode;
a dummy hole disposed on the dummy pattern and penetrating the inorganic insulating layers; and
a shielding layer disposed at least inside the dummy hole, and covering side surfaces of the inorganic insulating layers exposed by the dummy hole.

2. The display device of claim 1, further comprising:
an organic insulating layer disposed on the inorganic insulating layers, and covering the first transistor, the second transistor, and the shielding layer.

3. The display device of claim 1, wherein the shielding layer is a conductive pattern including a metal.

4. The display device of claim 3, wherein
the second transistor further comprises a first electrode disposed on the inorganic insulating layers and connected to a source region or a drain region of the first active layer, and
the first electrode and the shielding layer are disposed in a same layer on the substrate, and include a same conductive material.

5. The display device of claim 3, further comprising:
a power line adjacent to the dummy pattern,
wherein the shielding layer is connected to the power line.

6. The display device of claim 5, wherein
the power line is disposed on the inorganic insulating layers, and
the display device further comprises a connection pattern disposed between the first semiconductor layer and a conductive layer in which the shielding layer is disposed and connecting the shielding layer to the power line.

7. The display device of claim 6, wherein the connection pattern and the first gate electrode or the second gate electrode are disposed in a same layer.

8. The display device of claim 6, further comprising:
a capacitor electrode disposed between a conductive layer in which the first gate electrode is disposed and a conductive layer in which the second gate electrode is disposed on the substrate,
wherein the connection pattern and the capacitor electrode are disposed in a same layer.

9. The display device of claim 1, wherein the shielding layer is an inorganic insulating layer including nitrogen.

10. The display device of claim 9, wherein the shielding layer is a single-layer inorganic insulating layer comprising a silicon nitride layer or a silicon oxynitride layer.

11. The display device of claim 9, wherein the shielding layer is a multi-layer inorganic insulating layer comprising a silicon nitride layer or a silicon oxynitride layer and a silicon oxide layer.

12. The display device of claim 9, wherein the shielding layer has a refractive index of greater than or equal to about 1.6.

13. The display device of claim 1, further comprising:
pixels disposed in a display area on the substrate; and
a driving circuit disposed in a non-display area on the substrate, and connected to the pixels,
wherein the first transistor and the second transistor are provided in the driving circuit.

14. The display device of claim 13, wherein the dummy pattern, the dummy hole, and the shielding layer are disposed adjacent to the driving circuit.

15. The display device of claim 13, wherein the dummy pattern, the dummy hole, and the shielding layer are disposed between stage circuits provided in the driving circuit.

16. A method for manufacturing a display device, comprising:
sequentially forming, on a substrate, a first active layer and a dummy pattern, a first inorganic insulating layer covering the first active layer and the dummy pattern, a first gate electrode, a second inorganic insulating layer covering the first gate electrode, a second active layer, a third inorganic insulating layer covering the second active layer, a second gate electrode, and a fourth inorganic insulating layer covering the second gate electrode;
forming a contact hole penetrating the first to fourth inorganic insulating layers to expose a part of the first active layer and a dummy hole penetrating the first to fourth inorganic insulating layers to expose a part of the dummy pattern; and
forming a first electrode connected to the first active layer through the contact hole penetrating the first to fourth inorganic insulating layers, and a shielding layer at least inside the dummy hole to cover side surfaces of the first to fourth inorganic insulating layers exposed by the dummy hole.

17. The method of claim 16, further comprising:
forming an organic insulating layer covering the first electrode and the shielding layer, on the first to fourth inorganic insulating layers.

18. The method of claim 16, wherein in the forming of the first electrode and the shielding layer, the first electrode and the shielding layer are formed simultaneously using a conductive material including a metal.

19. The method of claim 18, further comprising:
forming a power line connected to the shielding layer, on the first to fourth inorganic insulating layers.

20. The method of claim 16, wherein the forming of the first electrode and the shielding layer comprises forming the first electrode using a conductive material, and forming the shielding layer using an inorganic insulating material including nitrogen.
